(19) United States
(12) Patent Application Publication
(10) Pub. No.: US 2026/0126577 A1
(43) Pub. Date: May 7, 2026

(54) POLARIZING PLATE AND DISPLAY DEVICE

(71) Applicant: FUJIFILM Corporation, Tokyo (JP)

(72) Inventors: Nobuyuki AKUTAGAWA, Minamiashigara-shi (JP); Shuhei OKUDA, Minamiashigara-shi (JP)

(73) Assignee: FUJIFILM Corporation, Tokyo (JP)

(21) Appl. No.: 19/441,874

(22) Filed: Jan. 7, 2026

Related U.S. Application Data
(63) Continuation of application No. PCT/JP2024/025286, filed on Jul. 12, 2024.

(30) Foreign Application Priority Data
Jul. 31, 2023 (JP) 2023-124401
Dec. 22, 2023 (JP) 2023-217088
Jan. 10, 2024 (JP) 2024-001662
Jun. 20, 2024 (JP) 2024-099468

(51) Int. Cl. G02B 5/30; H10K 59/80

(52) U.S. Cl. CPC G02B 5/3041; H10K 59/8791

(57) ABSTRACT

A polarizing plate includes a polarizer and an optical film configured to suppress in-plane tint unevenness and azimuthal angle dependence when a display device is viewed obliquely in a black display state. The optical film has an in-plane retardation of 130 to 150 nm at a wavelength of 550 nm and includes, from a polarizer side, a first optically anisotropic layer, an intimate attachment layer, and a second optically anisotropic layer. The first optically anisotropic layer has an in-plane retardation of 150 to 240 nm at 550 nm, and a ratio of the in-plane retardation to a thickness of the first optically anisotropic layer is 0.07 to 0.116.

### CROSS-REFERENCE TO RELATED APPLICATIONS

This application is a Continuation of PCT International Application No. PCT/JP2024/025286 filed on Jul. 12, 2024, which claims priority under 35 U.S.C. § 119 (a) to Japanese Patent Application No. 2023-124401 filed on Jul. 31, 2023, Japanese Patent Application No. 2023-217088 filed on Dec. 22, 2023, Japanese Patent Application No. 2024-001662 filed on Jan. 10, 2024, and Japanese Patent Application No. 2024-099468 filed on Jun. 20, 2024. The above applications are hereby expressly incorporated by reference, in their entirety, into the present application.

### BACKGROUND OF THE INVENTION

### 1. Field of the Invention

The present invention relates to a polarizing plate and a display device.

### 2. Description of the Related Art

An optically anisotropic layer having refractive index anisotropy is applied to various applications such as an anti-reflection film of various display devices such as an organic electroluminescence (EL) display device, and an optical compensation film of a liquid crystal display device.

For example, WO2022/045188A discloses an optical film in which three optically anisotropic layers exhibiting predetermined optical characteristics are laminated.

### SUMMARY OF THE INVENTION

In recent years, in the display device, it is required to further reduce an in-plane tint unevenness and a tint change depending on a direction (azimuthal angle) in which the display device is viewed in a black display state from an oblique direction. As a result of studying the display device using the optical film disclosed in the above document, the present inventors have found that the display device may not satisfy a level required in recent years.

The above-described in-plane tint unevenness is intended to mean that there are regions having different tints in a plane.

In view of the above-described circumstances, an object of the present invention is to provide a polarizing plate which is applied to a display element to obtain a display device, in which an in-plane tint unevenness is unlikely to occur and tint azimuthal angle dependence is suppressed in a case where the display device is viewed in a black display state from an oblique direction.

Another object of the present invention is to provide a display device.

As a result of conducting an extensive investigation to achieve the objects, the present inventors have found that the objects can be achieved by the following constitution.
[1] A polarizing plate comprising:
   a polarizer; and
   an optical film,
   in which an in-plane retardation of the optical film at a wavelength of 550 nm is 130 to 150 nm,
   the optical film includes a first optically anisotropic layer, an intimate attachment layer, and a second optically anisotropic layer from a polarizer side,
   an in-plane retardation of the first optically anisotropic layer at a wavelength of 550 nm is 150 to 240 nm, and
   a value obtained by dividing the in-plane retardation of the first optically anisotropic layer at a wavelength of 550 nm by a thickness of the first optically anisotropic layer is 0.07 to 0.116.
[2] The polarizing plate according to [1],
in which a thickness unevenness of the intimate attachment layer is 5 to 35 nm.
[3] The polarizing plate according to [1] or [2],
in which the in-plane retardation of the first optically anisotropic layer at the wavelength of 550 nm is 150 to 180 nm.
[4] The polarizing plate according to any one of [1] to [3],
in which the first optically anisotropic layer is a layer formed of a composition containing a disk-like liquid crystal compound.
[5] The polarizing plate according to any one of [1] to [4],
in which a thickness of the intimate attachment layer is 0.5 to 20 μm.
[6] The polarizing plate according to any one of [1] to [5],
in which the intimate attachment layer is an adhesive layer or a pressure-sensitive adhesive layer.
[7] The polarizing plate according to any one of [1] to [6],
in which the in-plane retardation of the optical film at the wavelength of 550 nm is 135 to 145 nm.
[8] A display device comprising:
a display element; and
the polarizing plate according to any one of [1] to [7].

According to the present invention, it is possible to provide a polarizing plate which is applied to a display element to obtain a display device, in which an in-plane tint unevenness is unlikely to occur and tint azimuthal angle dependence is suppressed in a case where the display device is viewed in a black display state from an oblique direction.

According to the present invention, it is possible to provide a display device.

### BRIEF DESCRIPTION OF THE DRAWINGS

FIG. 1 is an example of a schematic cross-sectional view of an embodiment of the polarizing plate of the present invention.

FIG. 2 is a view showing a relationship between an absorption axis of a polarizer and in-plane slow axes of optically anisotropic layers in the embodiment of the polarizing plate of the present invention shown in FIG. 1.

FIG. 3 is a schematic view showing the relationship between the absorption axis of the polarizer and the in-plane slow axes of the optically anisotropic layers in a case of being observed in a direction of a white arrow in FIG. 1.

FIG. 4 is an example of a schematic cross-sectional view of an embodiment of the polarizing plate of the present invention.

FIG. 5 is a view showing a relationship between an absorption axis of a polarizer and an in-plane slow axis of an optically anisotropic layer in the embodiment of the polarizing plate of the present invention shown in FIG. 4.

FIG. 6 is a schematic view showing the relationship between the absorption axis of the polarizer and the in-plane slow axis of the optically anisotropic layer in a case of being observed in a direction of a white arrow in FIG. 4.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

In the present specification, numerical ranges represented by “to” include numerical values before and after “to” as lower limit values and upper limit values.

In addition, in the present specification, in a case where there are two or more components corresponding to a certain component, “content” of such a component means the total content of the two or more components.

In the numerical range described stepwise in the present specification, the upper limit value or the lower limit value described in a certain numerical range may be replaced with the upper limit value or the lower limit value of another numerical range described stepwise. In addition, in the numerical range described in the present specification, an upper limit value and a lower limit value described in a certain numerical range may be replaced with values shown in Examples.

In the present specification, a combination of two or more preferred aspects is a more preferred aspect.

In the present specification, a slow axis is defined at a wavelength of 550 nm unless otherwise specified.

In the present specification, Re(λ) and Rth(λ) represent an in-plane retardation and a thickness-direction retardation at a wavelength 2, respectively. Unless otherwise specified, the wavelength λ is 550 nm.

In the present invention, Re(λ) and Rth(λ) are values measured at the wavelength of A in AxoScan (manufactured by Axometrics, Inc.). By inputting an average refractive index ((nx+ny+nz)/3) and a film thickness (d (μm)) in AxoScan, a slow axis direction (°), Re(λ)=Re(λ), and Rth(λ)=((nx+ny)/2−nz)×d are calculated.

Although Re(λ) is described as a numerical value calculated by AxoScan, it means Re(λ).

In the present specification, the refractive indices nx, ny, and nz are measured using an Abbe refractometer (NAR-4T, manufactured by Atago Co., Ltd.) and using a sodium lamp (2=589 nm) as a light source. In addition, in a case of measuring the wavelength dependence, it can be measured with a multi-wavelength Abbe refractometer DR-M2 (manufactured by Atago Co., Ltd.) in combination with a dichroic filter.

In addition, values in Polymer Handbook (John Wiley & Sons, Inc.) and catalogs of various optical films can be used. The values of the average refractive index of main optical films are exemplified below: cellulose acylate (1.48), cycloolefin polymer (1.52), polycarbonate (1.59), polymethyl methacrylate (1.49), and polystyrene (1.59).

“Light” in the present specification means actinic rays or radiation, and for example, means a bright line spectrum of a mercury lamp, far ultraviolet rays typified by an excimer laser, extreme ultraviolet rays (EUV light), X-rays, ultraviolet rays, electron beams (EB), or the like.

In the present specification, “visible light” means light having a wavelength of 380 to 780 nm. In addition, in the present specification, a measurement wavelength is 550 nm unless otherwise specified.

In the present specification, a relationship between angles (for example, “orthogonal”, “parallel”, and the like) is intended to include a range of errors acceptable in the art to which the present invention belongs. Specifically, it means that an angle is within an error range of less than +10° with respect to the exact angle, and the error with respect to the exact angle is preferably within a range of +5° or less and more preferably within a range of +3° or less.

In the present specification, a horizontal alignment of a rod-like liquid crystal compound refers to a state in which a major axis of a liquid crystal compound is arranged horizontally and in the same orientation with respect to the surface of the layer.

Here, the “horizontal” does not require to be strictly horizontal, but is intended to mean an alignment in which a tilt angle formed by an average molecular axis of the liquid crystal compound in the layer and the surface of the layer is less than 20°.

In addition, the “same orientation” does not require that the major axis of the liquid crystal compound is arranged strictly in the same orientation with respect to the surface of the layer, but is intended to mean that, in a case where the orientation of the slow axis is measured at any 20 positions in the plane, the maximum difference between slow axis orientations among the slow axis orientations at 20 positions (difference between two slow axis orientations having the maximum difference among the 20 slow axis orientations) is less than 10°.

A vertical alignment of the rod-like liquid crystal compound refers to a state in which the major axis of the rod-like liquid crystal compound is arranged perpendicularly and in the same orientation with respect to the surface of the layer. The “perpendicular” does not require to be strictly perpendicular, but is intended to mean an alignment in which a tilt angle between an average molecular axis in the layer and the surface of the layer is 70° to 110°. The same orientation is as described above.

A vertical alignment of a disk-like liquid crystal compound refers to a state in which a disc plane of the liquid crystal compound is arranged vertically and in the same orientation with respect to the surface of the layer. In addition, a horizontal alignment of a disk-like liquid crystal compound refers to a state in which a disc plane of the liquid crystal compound is arranged horizontally and in the same orientation with respect to the surface of the layer.

Here, the “vertical” does not require to be strictly perpendicular, but is intended to mean an alignment in which a tilt angle formed by the disc plane of the liquid crystal compound in the layer and the surface of the layer is 70° to 110°. The “horizontal” does not require to be strictly horizontal, but is intended to mean an alignment in which a tilt angle formed by the disc plane of the liquid crystal compound in the layer and the surface of the layer is 0°±20°.

In addition, the “same orientation” does not require that the major axis of the liquid crystal compound is arranged strictly in the same orientation with respect to the surface of the layer, but is intended to mean that, in a case where the orientation of the slow axis is measured at any 20 positions in the plane, the maximum difference between slow axis orientations among the slow axis orientations at 20 positions (difference between two slow axis orientations having the maximum difference among the 20 slow axis orientations) is less than 10°.

In the present specification, a C-plate is a plate that satisfies any of Expression (C1) or Expression (C2) in a case where a refractive index in an in-plane slow axis direction is defined as nx, a refractive index in a direction orthogonal to the in-plane slow axis in the plane is defined as ny, and a refractive index in a thickness direction is defined as nz. In a case where Expression (C1) is satisfied, the C-plate is a so-called positive C-plate; and in a case where Expression (C2) is satisfied, the C-plate is a so-called negative C-plate. The positive C-plate has an Rth showing a negative value and the negative C-plate has an Rth showing a positive value.

nz>nx≈ny Expression (C1)

nz<nx≈ny Expression (C2)

The symbol “≈” encompasses not only a case where both sides are completely the same as each other but also a case where the both sides are substantially the same as each other. The expression “substantially the same” means that, for example, a case where (nx−ny)×d (in which d is a thickness of a film) is 0 to 10 nm and preferably 0 to 5 nm is also included in “nx≈ny”.

### [Polarizing Plate]

Hereinafter, the polarizing plate according to the embodiment of the present invention will be described in detail.

The polarizing plate according to the embodiment of the present invention includes a polarizer and an optical film, in which an in-plane retardation of the optical film at a wavelength of 550 nm is 130 to 150 nm, the optical film includes a first optically anisotropic layer, an intimate attachment layer, and a second optically anisotropic layer from a polarizer side, an in-plane retardation of the first optically anisotropic layer at a wavelength of 550 nm is 150 to 240 nm, and a value obtained by dividing the in-plane retardation of the first optically anisotropic layer at a wavelength of 550 nm by a thickness of the first optically anisotropic layer is 0.07 to 0.116.

The reason why the polarizing plate having the above-described configuration can achieve the object of the present invention is not necessarily clear, but the present inventors speculate as follows.

The mechanism by which the effect is obtained is not limited by the following supposition. In other words, even in a case where an effect is obtained by a mechanism other than the following, it is included in the scope of the present invention.

A laminate including a polarizer and an optical film having an in-plane retardation of 130 to 150 nm at a wavelength of 550 nm has a function as a polarizing plate. It is found that, in the above-described optical film including the first optically anisotropic layer, the intimate attachment layer, and the second optically anisotropic layer in this order, in which the in-plane retardation of the first optically anisotropic layer at a wavelength of 550 nm is 150 to 240 nm, by adjusting a value (that is, refractive index anisotropy Δn) obtained by dividing the in-plane retardation at a wavelength of 550 nm by a thickness of the first optically anisotropic layer to a predetermined range, it is possible to suppress an in-plane tint unevenness and tint azimuthal angle dependence in a case where a display device which is obtained by applying the optical film to a display element is viewed in a black display state from an oblique direction.

Hereinafter, the fact that the in-plane tint unevenness is unlikely to occur and the fact that the tint azimuthal angle dependence is suppressed in a case where a display device which is obtained by applying the optical film to a display element is viewed in a black display state from an oblique direction are simply referred to as “in-plane tint unevenness can be suppressed” and “tint azimuthal angle dependence can be suppressed”, respectively; and the fact that at least one of the in-plane tint unevenness can be further suppressed or the tint azimuthal angle dependence can be further suppressed is also referred to as “effect of the present invention is more excellent”.

Hereinafter, each member which can be included in the polarizing plate according to the embodiment of the present invention will be described in detail.

### [Optical Film]

The polarizing plate according to the embodiment of the present invention includes an optical film.

The optical film includes a first optically anisotropic layer, an intimate attachment layer, and a second optically anisotropic layer in this order from a polarizer side.

The optical film has an in-plane retardation of 130 to 150 nm at a wavelength of 550 nm. From the viewpoint that the effect of the present invention is more excellent, the in-plane retardation of the optical film at a wavelength of 550 nm is preferably 135 nm or more. In addition, from the viewpoint that the effect of the present invention is more excellent, the in-plane retardation of the optical film at a wavelength of 550 nm is preferably 145 nm or less.

### <First Optically Anisotropic Layer>

The first optically anisotropic layer is preferably a layer formed of a composition containing a liquid crystal compound, and more preferably a layer in which an aligned liquid crystal compound is immobilized.

In the present specification, the “immobilized” liquid crystal compound means a state in which the alignment of the liquid crystal compound is maintained. Specifically, the “immobilized” state is more preferably a state in which, in a temperature range of usually 0° C. to 50° C. or in a temperature range of −30° C. to 70° C. under more severe conditions, the layer has no fluidity and a fixed alignment morphology can be stably maintained without causing a change in the alignment morphology due to an external field or an external force.

The above-described liquid crystal compound may be a disk-like liquid crystal compound or a rod-like liquid crystal compound.

A known compound can be used as the disk-like liquid crystal compound.

Examples of the disk-like liquid crystal compound include compounds described in paragraphs to of JP2007-108732A and paragraphs to of JP2010-244038A.

A known compound can be used as the rod-like liquid crystal compound.

Examples of the rod-like liquid crystal compound include compounds described in claim 1 of JP1999-513019A (JP-H11-513019A) and paragraphs to of JP2005-289980A.

The liquid crystal compound may have a polymerizable group, and from the viewpoint that the alignment can be fixed, a liquid crystal compound having a polymerizable group (polymerizable liquid crystal compound) is preferable.

In the present specification, the type of the polymerizable group is not particularly limited, but is preferably a functional group capable of an addition polymerization reaction, more preferably a polymerizable ethylenically unsaturated group or a ring-polymerizable group, and still more preferably a (meth)acryloyl group, a vinyl group, a styryl group, or an allyl group.

The in-plane retardation of the first optically anisotropic layer at a wavelength of 550 nm is 150 nm or more; and from the viewpoint that the effect of the present invention is more excellent, it is preferably 155 nm or more, and more preferably 160 nm or more. In addition, the in-plane retardation of the first optically anisotropic layer at a wavelength of 550 nm is 240 nm or less; and from the viewpoint that the effect of the present invention is more excellent, it is preferably 220 nm or less, more preferably 200 nm or less, and still more preferably 180 nm or less.

A value (Re/d) obtained by dividing the in-plane retardation Re of the first optically anisotropic layer at a wavelength of 550 nm by a thickness d of the first optically anisotropic layer is 0.07 or more; and from the viewpoint that the effect of the present invention is more excellent, it is preferably 0.08 or more, and more preferably 0.09 or more. The Re/d is 0.116 or less; and from the viewpoint that the effect of the present invention is more excellent, it is preferably 0.113 or less, and more preferably 0.110 or less.

In other words, the refractive index anisotropy Δn of the first optically anisotropic layer at a wavelength of 550 nm is 0.07 to 0.116, preferably 0.09 to 0.11.

In a case where the Re/d is less than 0.07, the tint azimuthal angle dependence is strongly observed, which is not preferable from the viewpoint that aligning properties of the liquid crystal are deteriorated; and in a case of being more than 0.116, the in-plane tint unevenness is strongly observed, which is not preferable.

The thickness of the first optically anisotropic layer is not particularly limited as long as the Re/d is a value satisfying the above-described requirement, but is preferably 0.5 μm or more, more preferably 1.0 μm or more, still more preferably 1.3 μm or more, and particularly preferably 1.4 μm or more. In addition, the thickness of the first optically anisotropic layer is preferably 5.0 μm or less, more preferably 3.0 μm or less, still more preferably 2.5 μm or less, and particularly preferably 2.2 μm or less.

The above-described thickness is obtained by measuring thicknesses of any five or more points of the first optically anisotropic layer and arithmetically averaging the measured values.

From the viewpoint that the optical film can be thinned and the effect of the present invention is more excellent, an average refractive index of the first optically anisotropic layer is preferably 1.50 to 1.70 and more preferably 1.55 to 1.65.

An angle between an in-plane slow axis of the first optically anisotropic layer and an absorption axis of the polarizer is preferably 40° to 85°, more preferably 50° to 85°, and still more preferably 65° to 85°.

The first optically anisotropic layer may be composed of one optically anisotropic layer, or two or more optically anisotropic layers. From the viewpoint that the optical film can be thinned, the first optically anisotropic layer is preferably composed of one optically anisotropic layer.

From the viewpoint that the effect of the present invention is more excellent, the first optically anisotropic layer is preferably a layer formed of a composition containing a disk-like liquid crystal compound, and more preferably a layer in which a vertically aligned disk-like liquid crystal compound is immobilized.

The first optically anisotropic layer may be a layer formed of a composition containing a rod-like liquid crystal compound, and in this case, the first optically anisotropic layer is preferably a layer in which a horizontally aligned rod-like liquid crystal compound is immobilized.

### <Intimate Attachment Layer>

The intimate attachment layer is not particularly limited as long as it is a layer having a function of closely attaching the first optically anisotropic layer and the second optically anisotropic layer.

As the intimate attachment layer, for example, an adhesive layer or a pressure-sensitive adhesive layer can be used.

The adhesive layer is a layer formed of an adhesive. Examples of the adhesive include an active energy ray-curable adhesive, an aqueous adhesive, a solvent-type adhesive, an emulsion-type adhesive, a solvent-free adhesive, and a thermosetting adhesive; and an active energy ray-curable adhesive is preferable.

Examples of the active energy ray-curable adhesive include an electron beam-curable adhesive, an ultraviolet curable adhesive, and a visible light-curable adhesive; and an ultraviolet curable adhesive is preferable.

As the active energy ray-curable adhesive, for example, a known adhesive can be used, and an adhesive selected from a (meth)acrylate-based adhesive or an epoxy-based adhesive is preferable.

Examples of a curable component in the (meth)acrylate-based adhesive include a compound having a (meth)acryloyl group and a compound having a vinyl group. Examples of a curable component in the epoxy-based adhesive include a compound having a glycidyl group.

A method of forming the adhesive layer is not particularly limited, and examples thereof include a method of applying the adhesive onto at least one layer selected from the first optically anisotropic layer or the second optically anisotropic layer, bonding the first optically anisotropic layer and the second optically anisotropic layer to each other, and curing the adhesive.

As the above-described application method, a roll coating method such as reverse coating or gravure coating, a spin coating method, a screen coating method, a fountain coating method, a dipping method, or a spraying method can be employed.

The pressure-sensitive adhesive layer is a layer containing a pressure-sensitive adhesive, and a known pressure-sensitive adhesive layer can be used.

Examples of the pressure-sensitive adhesive contained in the pressure-sensitive adhesive layer include an acrylic pressure-sensitive adhesive, an epoxy-based pressure-sensitive adhesive, a rubber-based pressure-sensitive adhesive, a silicone-based pressure-sensitive adhesive, a urethane-based pressure-sensitive adhesive, a vinyl alkyl ether-based pressure-sensitive adhesive, a polyvinyl alcohol-based pressure-sensitive adhesive, a polyvinylpyrrolidone-based pressure-sensitive adhesive, a polyacrylamide-based pressure-sensitive adhesive, and a cellulose-based pressure-sensitive adhesive.

Among these, from the viewpoint of excellent transparency, weather fastness, heat resistance, and the like, an acrylic pressure-sensitive adhesive is preferable.

The acrylic pressure-sensitive adhesive is preferably a copolymer of a (meth)acrylate in which an alkyl group in an ester moiety is an alkyl group having 20 or less carbon atoms, such as a methyl group, an ethyl group, and a butyl group, with (meth)acrylic acid or a (meth)acrylic monomer having a functional group such as hydroxyethyl (meth)acrylate.

As the pressure-sensitive adhesive, reference can be made to the description in to of JP2018-60014A, the contents of which are incorporated herein by reference.

A method of forming the pressure-sensitive adhesive layer is not particularly limited, and examples thereof include a method of applying a solution of the pressure-sensitive adhesive onto a release sheet, drying the solution, and then transferring the layer to at least one layer selected from the first optically anisotropic layer or the second optically anisotropic layer; and a method of applying a solution in which the pressure-sensitive adhesive is dissolved or dispersed in a solvent (for example, toluene and ethyl acetate) onto a surface of at least one layer selected from the first optically anisotropic layer or the second optically anisotropic layer, and drying the solution.

As the above-described application method, the methods described as the method of applying the adhesive can be used.

Examples of a constituent material of the above-described release sheet include appropriate thin paper bodies, for example, synthetic polymer films such as polyethylene, polypropylene, and polyethylene terephthalate, rubber sheets, paper, cloth, nonwoven fabrics, nets, foam sheets, and metal foils.

From the viewpoint that the effect of the present invention is more excellent, a thickness of the intimate attachment layer is preferably 0.5 μm or more, more preferably 1 μm or more, and still more preferably 2 μm or more. In addition, from the viewpoint that the effect of the present invention is more excellent, the thickness of the intimate attachment layer is preferably 50 μm or less, more preferably 20 μm or less, and still more preferably 10 μm or less.

The thickness of the intimate attachment layer is calculated by measuring a refractive index of the optical film (objective lens: 5 times) using a microspectroscopic film thickness meter (OPTM, manufactured by Otsuka Electronics Co., Ltd.) and performing Fourier transformation using analysis software in the device (operating wavelength: 400 to 800 nm, Bell function: Yes). Specifically, a peak corresponding to an optical film thickness of each of the optically anisotropic layers and the intimate attachment layer is detected from a power spectrum calculated by performing Fourier transformation under the above-described conditions, and the thickness of the intimate attachment layer is calculated by dividing the optical film thickness of the intimate attachment layer by a refractive index of the intimate attachment layer. The measurement and the calculation are performed at 1 mm intervals for 3 cm at any position of the optical film, and an average value of calculation results at 31 points is defined as “thickness of the intimate attachment layer”.

A thickness unevenness σ (unit: nm) of the intimate attachment layer is often 100 nm or less, and from the viewpoint that the effect of the present invention is more excellent, it is preferably 35 nm or less, and more preferably less than 10 nm. In addition, from the viewpoint that air bubbles are less likely to be entrapped in a case of bonding the first optically anisotropic layer and the second optically anisotropic layer, the thickness unevenness σ of the intimate attachment layer is preferably 5 nm or more. That is, the thickness unevenness σ of the intimate attachment layer is preferably 5 to 35 nm, and still more preferably 5 nm or more and less than 10 nm.

The thickness unevenness σ of the intimate attachment layer is a value calculated as a standard deviation of the thicknesses of the intimate attachment layer at 31 points obtained in the measurement of the thickness of the intimate attachment layer described above.

A method of adjusting the above-described thickness unevenness of the intimate attachment layer is not particularly limited, and examples thereof include a method of adjusting a formulation, a viscosity, and an application method of a composition for forming the intimate attachment layer, and conditions in a case of bonding the first optically anisotropic layer and the second optically anisotropic layer through the intimate attachment layer.

From the viewpoint that the effect of the present invention is more excellent, an average refractive index of the intimate attachment layer is preferably 1.48 to 1.70 and more preferably 1.55 to 1.67.

From the viewpoint that the effect of the present invention is more excellent, an absolute value of a difference between the average refractive index of the intimate attachment layer and the average refractive index of the first optically anisotropic layer is preferably 0 to 0.50 and more preferably 0 to 0.20.

### <Second Optically Anisotropic Layer>

The second optically anisotropic layer is preferably a layer formed of a composition containing an aligned liquid crystal compound, and more preferably a layer in which an aligned liquid crystal compound is immobilized.

Examples of the above-described liquid crystal compound include the same liquid crystal compounds as those in the first optically anisotropic layer described above.

A value of a product And of a refractive index anisotropy Δn of the second optically anisotropic layer at a wavelength of 550 nm and a thickness d of the second optically anisotropic layer is preferably 100 nm or more, more preferably 105 nm or more, and still more preferably 110 nm or more. In addition, the value of the And is preferably 220 nm or less, more preferably 200 nm or less, and still more preferably 190 nm or less.

The refractive index anisotropy Δn means refractive index anisotropy of an optically anisotropic layer.

The Δnd is measured using AxoScan (polarimeter) device manufactured by Axometrics, Inc. and using device analysis software of Axometrics, Inc.

From the viewpoint that the effect of the present invention is more excellent, the thickness of the second optically anisotropic layer is preferably 0.5 μm or more, more preferably 0.8 μm or more, still more preferably 1.0 μm or more, and particularly preferably 1.5 μm or more. In addition, the thickness of the second optically anisotropic layer is preferably 5.0 μm or less, more preferably 3.0 μm or less, and still more preferably 2.5 μm or less.

A method of measuring the thickness of the second optically anisotropic layer is as described above.

From the viewpoint that the optical film can be thinned and the effect of the present invention is more excellent, an average refractive index of the second optically anisotropic layer is preferably 1.50 to 1.70 and more preferably 1.55 to 1.65.

The second optically anisotropic layer may be composed of one optically anisotropic layer, or two or more optically anisotropic layers.

From the viewpoint that the effect of the present invention is more excellent, the second optically anisotropic layer is preferably selected from a laminate (hereinafter, also referred to as “optically anisotropic layer (AB)”) of an optically anisotropic layer in which a twist-aligned rod-like liquid crystal compound having a helical axis in a thickness direction is immobilized (hereinafter, also referred to as “optically anisotropic layer (A)”) and an optically anisotropic layer in which a vertically aligned rod-like liquid crystal compound is immobilized (hereinafter, also referred to as “optically anisotropic layer (B)”), and an optically anisotropic layer in which a vertically aligned disk-like liquid crystal compound is immobilized (hereinafter, also referred to as “optically anisotropic layer (C)”), and more preferably the optically anisotropic layer (AB).

### (Optically Anisotropic Layer (AB))

The optically anisotropic layer (AB) is an optically anisotropic layer in which the optically anisotropic layer (A) and the optically anisotropic layer (B) are laminated, and it is preferable that the optically anisotropic layer (A) and the optically anisotropic layer (B) are laminated in this order from the intimate attachment layer side.

### —Optically Anisotropic Layer (A)—

As described above, the optically anisotropic layer (A) is an optically anisotropic layer in which a twist-aligned rod-like liquid crystal compound having a helical axis in a thickness direction is immobilized, and it is preferably a layer in which a chiral nematic phase having a so-called helical structure is fixed.

It is preferable that the optically anisotropic layer (A) is formed of a composition containing a rod-like liquid crystal compound exhibiting a nematic liquid crystal phase and a chiral agent described later.

The above-described rod-like liquid crystal compound is not particularly limited, and examples thereof include the rod-like liquid crystal compounds which can be contained in the first optically anisotropic layer described above.

A twisted angle of the rod-like liquid crystal compound (twisted angle of liquid crystal compound in an alignment axis direction) is not particularly limited, and is often more than 0° and 360° or less; and from the viewpoint that the effect of the present invention is more excellent, it is preferably 80°+30° (within a range of 50° to) 110°, more preferably 80°±20° (within a range of 60° to) 100°, and still more preferably more preferably 80°±10° (within a range of 70° to) 90°.

The twisted angle is measured using AxoScan (polarimeter) device manufactured by Axometrics, Inc. and using device analysis software of Axometrics, Inc.

In addition, the “twist-aligned liquid crystal compound” is intended to that the liquid crystal compound from one main surface to the other main surface of the optically anisotropic layer (A) is twisted around the thickness direction of the optically anisotropic layer (A) as an axis. Along with this, the alignment axis direction (in-plane slow axis direction) of the liquid crystal compound varies depending on the position of the optically anisotropic layer (A) in the thickness direction.

An angle between the in-plane slow axis of the first optically anisotropic layer and an in-plane slow axis of the optically anisotropic layer (A) on the intimate attachment layer-side surface is preferably 0° to 20° and more preferably 0° to 15°.

A value of a product And of a refractive index anisotropy Δn of the optically anisotropic layer (A) at a wavelength of 550 nm and a thickness d of the optically anisotropic layer (A) is preferably 140 nm or more, more preferably 150 nm or more, and still more preferably 160 nm or more. In addition, the value of the And is preferably 220 nm or less, more preferably 210 nm or less, and still more preferably 200 nm or less.

A method of obtaining the And is as described above.

The thickness of the optically anisotropic layer (A) is not particularly limited, but is preferably 0.5 μm or more, more preferably 1.0 μm or more, and still more preferably 1.3 μm or more. In addition, the thickness of the optically anisotropic layer (A) is preferably 5.0 μm or less, more preferably 2.5 μm or less, and still more preferably 2.2 μm or less.

The above-described thickness is obtained by measuring thicknesses of any five or more points of the optically anisotropic layer (A) and arithmetically averaging the measured values.

### —Optically Anisotropic Layer (B)—

As described above, the optically anisotropic layer (B) is a layer in which a vertically aligned rod-like liquid crystal compound is immobilized.

It is preferable that the optically anisotropic layer (B) is formed of a composition containing a rod-like liquid crystal compound and a photo-alignment polymer described later.

The above-described rod-like liquid crystal compound is not particularly limited, and examples thereof include the liquid crystal compounds which can be contained in the first optically anisotropic layer described above.

An in-plane retardation of the optically anisotropic layer (B) at a wavelength of 550 nm is preferably 0 to 10 nm and more preferably 0 to 5 nm.

A thickness direction retardation of the optically anisotropic layer (B) at a wavelength of 550 nm is preferably-120 nm or more, more preferably-110 nm or more, and still more preferably-100 nm or more. In addition, the thickness direction retardation of the optically anisotropic layer (B) at a wavelength of 550 nm is preferably-20 nm or less, more preferably −30 nm or less, and still more preferably-40 nm or less.

A thickness of the optically anisotropic layer (B) is not particularly limited, but is preferably 10.0 μm or less, more preferably 5.0 μm or less, and still more preferably 2.0 μm or less. In addition, the thickness of the optically anisotropic layer (B) is preferably 0.1 μm or more, and more preferably 0.3 μm or more.

The above-described thickness is obtained by measuring thicknesses of any five or more points of the optically anisotropic layer (B) and arithmetically averaging the measured values.

### (Optically Anisotropic Layer (C))

As described above, the optically anisotropic layer (C) is a layer in which a vertically aligned disk-like liquid crystal compound is immobilized.

The disk-like liquid crystal compound is not particularly limited, and examples thereof include the disk-like liquid crystal compounds which can be contained in the first optically anisotropic layer described above.

An angle between the absorption axis of the polarizer and an in-plane slow axis of the optically anisotropic layer (C) is preferably 0° to 30°, more preferably 5° to 25°, and still more preferably 10° to 20°.

An angle between the in-plane slow axis of the first optically anisotropic layer and the in-plane slow axis of the optically anisotropic layer (C) is preferably 60°±30° (within a range of 30° to) 90°, more preferably 60°±20° (within a range of 40° to) 80°, and still more preferably 60°±10° (within a range of 50° to) 70°.

An in-plane retardation of the optically anisotropic layer (C) at a wavelength of 550 nm is preferably 100 nm or more, and more preferably 105 nm or more. In addition, the in-plane retardation of the optically anisotropic layer (C) at a wavelength of 550 nm is preferably 150 nm or less, and more preferably 145 nm or less.

A thickness of the optically anisotropic layer (C) is not particularly limited, but is preferably 10.0 μm or less, more preferably 5.0 μm or less, and still more preferably 2.0 μm or less. In addition, the thickness of the optically anisotropic layer (C) is preferably 0.1 μm or more, and more preferably 0.3 μm or more.

The above-described thickness is obtained by measuring thicknesses of any five or more points of the optically anisotropic layer (C) and arithmetically averaging the measured values.

### <Other Layers>

The optical film may include a layer other than the first optically anisotropic layer, the intimate attachment layer, and the second optically anisotropic layer described above as long as the functions of the present invention are not hindered.

Examples of other layers include an optically anisotropic layer different from the first optically anisotropic layer and the second optically anisotropic layer described above, and an intimate attachment layer.

It is also preferable that the third optically anisotropic layer is disposed between the polarizer and the first optically anisotropic layer. That is, it is also preferable that the optical film includes the third optically anisotropic layer on the surface of the first optically anisotropic layer on the polarizer side.

The third optically anisotropic layer is preferably a layer formed of a composition containing an aligned liquid crystal compound, and more preferably a layer in which the aligned liquid crystal compound is immobilized. Examples of the above-described liquid crystal compound include the same liquid crystal compounds as those in the first optically anisotropic layer described above.

As the third optically anisotropic layer, a layer in which a horizontally aligned disk-like liquid crystal compound is immobilized is preferable. By using such a layer, it is possible to further reduce the tint change in a case of being viewed from an oblique direction and to obtain favorable visibility. In this case, since the polarizer and the third optically anisotropic layer and the third optically anisotropic layer and the first optically anisotropic layer are bonded to each other, it is also preferable to use the intimate attachment layer as described above. From the viewpoint of suppressing interfacial reflection, it is also preferable that the intimate attachment layer is not disposed, the optically anisotropic layer is formed by directly laminating and applying the composition for forming an optically anisotropic layer, or plasma bonding or the like is performed. In addition, it is also preferable that the refractive index is inclined from the inside of the liquid crystal layer (optically anisotropic layer) toward the surface layer side. In addition, the interfacial reflection suppression can be applied to any optically anisotropic layer of the optical film, and the effect is further exhibited by applying to the first optically anisotropic layer and the second optically anisotropic layer.

An in-plane retardation of the third optically anisotropic layer at a wavelength of 550 nm is preferably 0 to 10 nm and more preferably 0 to 5 nm.

A thickness direction retardation of the third optically anisotropic layer at a wavelength of 550 nm is preferably 10 nm or more and 100 nm or less, more preferably 20 nm or more and 80 nm or less, and still more preferably 20 nm or more and 50 nm or less.

A thickness of the third optically anisotropic layer is not particularly limited, but is preferably 0.1 μm or more and 10.0 μm or less, more preferably 0.3 μm or more and 5.0 μm or less, and still more preferably 0.3 μm or more and 2.0 μm or less.

The above-described thickness is obtained by measuring thicknesses of any five or more points of the third optically anisotropic layer and arithmetically averaging the measured values.

The third optically anisotropic layer and the polarizer, and the third optically anisotropic layer and the first optically anisotropic layer are disposed directly or through an intimate attachment layer. Examples of the intimate attachment layer include the intimate attachment layer described above. On one or both surfaces of the third optically anisotropic layer, a difference between a refractive index (average refractive index) of the surface of the third optically anisotropic layer and a refractive index (average refractive index) of a layer in contact with the surface of the third optically anisotropic layer is preferably 0.20 or less, more preferably 0.10 or less, and still more preferably 0.05 or less.

### [Polarizer]

The polarizer included in the polarizing plate according to the embodiment of the present invention may be a member having a function of converting natural light into specific linearly polarized light, and examples thereof include an absorption type polarizer.

The type of the polarizer is not particularly limited, and a commonly used polarizer can be used. Examples thereof include an iodine-based polarizer, a dye-based polarizer using a dichroic dye, and a polyene-based polarizer. The iodine-based polarizer and the dye-based polarizer are generally produced by adsorbing iodine or a dichroic dye on a polyvinyl alcohol, followed by stretching.

A protective film may be disposed on one side or both sides of the polarizer.

In addition, as described in WO2019/131943A and JP2017-083843A, a coating type polarizer produced by using and applying a liquid crystal compound and a dichroic organic coloring agent (for example, a dichroic azo coloring agent used for a light-absorbing anisotropic film described in WO2017/195833A), without using a polyvinyl alcohol as a binder, may be used as the polarizer. That is, the polarizer may be a polarizer formed of a composition containing a polymerizable liquid crystal compound.

The coating type polarizer is a technique which utilizes the alignment of the liquid crystal compound to align the dichroic organic coloring agent. As described in JP2012-083734A, in a case where the polymerizable liquid crystal compound exhibits smectic properties, it is preferable from the viewpoint of increasing the alignment degree. Alternatively, as described in WO2018/186503A, it is also preferable to crystallize a coloring agent from the viewpoint of increasing the alignment degree. WO2019/131943A describes a structure of a polymer liquid crystal which is preferred for increasing the alignment degree.

A polarizer in which a dichroic organic coloring agent is aligned using the aligning properties of the liquid crystal without carrying out stretching has the following characteristics. The above-described polarizer has many advantages, such as being able to be made very thin with a thickness of approximately 0.1 to 5 μm; as described in JP2019-194685A, being difficult for cracks to occur in a case of being bent, and being less likely to undergo thermal deformation; and as described in JP6483486B, exhibiting excellent durability even with a polarizing plate having a high transmittance of more than 50%.

By utilizing these advantages, the polarizer can be used in applications that require high brightness or small size and light weight, applications of a fine optical system, applications of forming into a portion having a curved surface, or applications of a flexible portion. In addition, it is also possible to peel off a support and transfer the polarizer for use.

The polarizing plate may include a polarizer protective film. A configuration of the above-described polarizer protective film is not particularly limited, and may be any of a support and a coating layer of the polarizer, or a laminate of a support and a coating layer.

As the coating layer, a known layer can be used, and examples thereof include a layer obtained by polymerizing and curing a polymer and a polyfunctional monomer. Examples of the polymer include a (meth)acrylic polymer and a cycloolefin polymer. Examples of the polymerizable monomer include radically polymerizable compounds and cationically polymerizable compounds.

In addition, the support may have a function as an optically anisotropic layer. In a case where the support has a function as an optically anisotropic layer, an in-plane retardation of the support at a wavelength of 550 nm is preferably 0 to 10 nm and more preferably 0 to 5 nm. In addition, a thickness direction retardation at a wavelength of 550 nm is preferably 10 to 100 nm, more preferably 20 to 80 nm, and still more preferably 20 to 50 nm.

### [Other Members]

The polarizing plate may include a member other than the polarizer and the optical film as long as the effect of the present invention is not impaired. Examples of other members include an alignment film and a substrate.

### <Alignment Film>

The polarizing plate may include an alignment film. The alignment film may be disposed on the substrate described later or may be disposed between the optically anisotropic layers.

The alignment film can be formed by a rubbing treatment of an organic compound (preferably a polymer), oblique vapor deposition of an inorganic compound, formation of a layer having microgrooves, accumulation of an organic compound (for example, w-tricosanoic acid, dioctadecylmethylammonium chloride, or methyl stearate) by the Langmuir-Blodgett method (LB film), and the like.

In addition to the above, the alignment film may be an alignment film in which an alignment function is imparted by applying an electric field, applying a magnetic field, or irradiating with light (preferably polarized light).

Examples of the alignment film also include a photo-alignment film. In a case where the photo-alignment film is used, the rubbing treatment is not required, and thus problems such as defects caused by rubbing dust do not occur, so that a liquid crystal cured film having few defects can be obtained as the optically anisotropic layer. As the photo-alignment film, a known compound can be used, but it is preferable to use a polymer having a cinnamoyl structure described in WO2019/225632A.

A thickness of the alignment film is not particularly limited as long as it can exhibit the alignment function, but is preferably 0.01 to 5.0 μm, more preferably 0.05 to 3.0 μm, and still more preferably 0.5 to 1.0 μm.

In a case where the alignment film is disposed on the substrate, the alignment film may be peelable from the optically anisotropic layer together with the substrate.

### <Substrate>

The polarizing plate may include a substrate.

The substrate is preferably a transparent substrate. The transparent substrate is intended to be a substrate having a transmittance of visible light (average transmittance in a visible light region) of 60% or more, and the transmittance is preferably 80% or more and more preferably 90% or more. The upper limit thereof is not particularly limited, but is preferably 99.9% or less.

A thickness of the substrate is not particularly limited, but is preferably 10 to 200 μm, more preferably 10 to 100 μm, and still more preferably 20 to 90 μm.

The substrate may contain various additives (for example, an optical anisotropy adjuster, a wavelength dispersion adjuster, a fine particle, a plasticizer, an ultraviolet inhibitor, a deterioration inhibitor, a release agent, and the like).

A plurality of substrates may be laminated.

In addition, the substrate may undergo a surface treatment (for example, a glow discharge treatment, a corona discharge treatment, an ultraviolet (UV) treatment, or a flame treatment) on the surface of the substrate in order to improve adhesion with layers provided thereon.

In addition, an adhesive layer (undercoat layer) may be provided on the substrate.

In addition, in order to impart slipperiness in a transport step and prevent a back surface and a front surface from sticking to each other after winding, a polymer layer in which inorganic particles having an average particle diameter of approximately 10 to 100 nm are mixed in a solid content mass ratio of 5% to 40% by mass may be disposed on one side of the substrate.

The substrate may be a so-called temporary support. That is, after manufacturing the polarizing plate according to the embodiment of the present invention on the substrate, the substrate may be peeled off from the optically anisotropic layer as necessary.

In a case where the above-described alignment film is formed on the surface of the substrate, the rubbing treatment may be directly performed on the surface of the substrate. That is, a substrate which has been subjected to the rubbing treatment may be used. A direction of the rubbing treatment is not particularly limited, and an optimum direction is appropriately selected according to the direction in which the liquid crystal compound is desired to be aligned.

A treatment method widely adopted as a liquid crystal alignment treatment step of a liquid crystal display (LCD) can be applied for the rubbing treatment. That is, a method of obtaining alignment by rubbing the surface of the substrate in a certain direction with paper, gauze, felt, rubber, nylon fiber, polyester fiber, or the like can be used.

### [Suitable Aspect of Polarizing Plate]

In the polarizing plate according to the embodiment of the present invention, a combination of the first optically anisotropic layer and the second optically anisotropic layer in the optical film is appropriately selected within a range satisfying the requirements of the present invention; but is preferably a polarizing plate of an aspect 1 or a polarizing plate of an aspect 2, and more preferably a polarizing plate of an aspect 1 from the viewpoint that the tint in a black display state can be further suppressed.

(Aspect 1) The first optically anisotropic layer is a layer in which a vertically aligned disk-like liquid crystal compound is immobilized, and the second optically anisotropic layer is the optically anisotropic layer (AB).

(Aspect 2) The first optically anisotropic layer is a layer in which a vertically aligned disk-like liquid crystal compound is immobilized or a layer in which a horizontally aligned rod-like liquid crystal compound is immobilized, and the second optically anisotropic layer is the optically anisotropic layer (C).

The definitions and suitable aspects of the layer in which the vertically aligned disk-like liquid crystal compound is immobilized, the optically anisotropic layer (AB), the layer in which the horizontally aligned rod-like liquid crystal compound is immobilized, and the optically anisotropic layer (C) in each aspect are as described above.

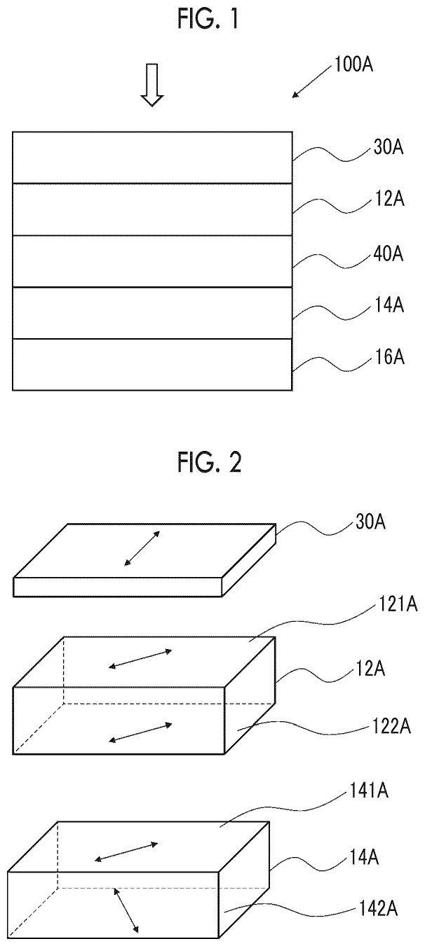

The polarizing plate of the aspect 1 described above will be described with reference to FIGS. 1 to 3.

FIG. 1 is a schematic cross-sectional view of a polarizing plate 100A of the aspect 1.

FIG. 2 is a view showing a relationship between an absorption axis of a polarizer 30A and in-plane slow axes of a first optically anisotropic layer 12A and an optically anisotropic layer (A) 14A in the polarizing plate 100A of the aspect 1 shown in FIG. 1. An arrow in the polarizer 30A in FIG. 2 represents the absorption axis, and arrows in the first optically anisotropic layer 12A and the optically anisotropic layer (A) 14A represent the in-plane slow axes in the layers, respectively.

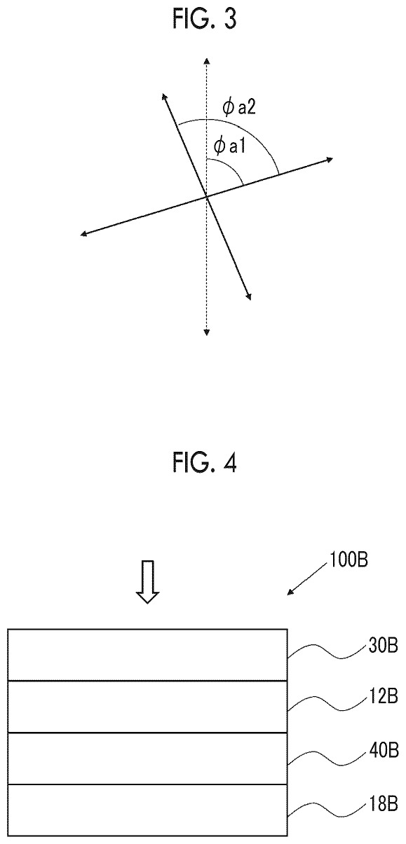

FIG. 3 is a view showing a relationship between the absorption axis (broken line) of the polarizer 30A and the in-plane slow axes (solid lines) of the first optically anisotropic layer 12A and the optically anisotropic layer (A) 14A in a case of being observed from a white arrow side of FIG. 1. A rotation angle of the in-plane slow axes is represented by a positive angle value in a counterclockwise direction and a negative angle value in a clockwise direction, with respect to the absorption axis of the polarizer 30A (0°), upon observation from the white arrow side in FIG. 1. In addition, whether the twisted direction of the liquid crystal compound is a right-handed twist (clockwise) or a left-handed twist (counterclockwise) is determined with reference to the in-plane slow axis on the surface of the polarizer 30A side in the optically anisotropic layer (A) 14A, upon observation from the white arrow side in FIG. 1.

As shown in FIG. 1, the polarizing plate 100A of the first aspect includes the polarizer 30A, the first optically anisotropic layer 12A, an intimate attachment layer 40A, the optically anisotropic layer (A) 14A, and an optically anisotropic layer (B) 16A in this order. The laminate of the optically anisotropic layer (A) 14A and the optically anisotropic layer (B) 16A constitutes the second optically anisotropic layer. The polarizing plate 100A may include an intimate attachment layer (not shown) between the polarizer 30A and the first optically anisotropic layer 12A, or may include an optically anisotropic layer (for example, the third optically anisotropic layer) (not shown).

In the polarizing plate 100A of the first aspect, as shown in FIGS. 2 and 3, an angle φa1 between the absorption axis of the polarizer 30A and the first optically anisotropic layer 12A is 76°. More specifically, the in-plane slow axis of the first optically anisotropic layer 12A is rotated by −76° (76° clockwise) with respect to the absorption axis of the polarizer 30A. In FIGS. 2 and 3, φa1 is 76°; but the present invention is not limited to this aspect, and pal is preferably 40° to 85°, more preferably 50° to 85°, and still more preferably 65° to 85°.

In addition, as shown in FIG. 2, in the first optically anisotropic layer 12A, the in-plane slow axis on a surface 121A of the first optically anisotropic layer 12A on the polarizer 30A side is parallel to the in-plane slow axis on a surface 122A of the first optically anisotropic layer 12A on the optically anisotropic layer (A) 14A side.

As shown in FIGS. 2 and 3, the in-plane slow axis on a surface 141A of the optically anisotropic layer (A) 14A on the first optically anisotropic layer 12A side is parallel to the in-plane slow axis of the first optically anisotropic layer 12A.

As described above, the optically anisotropic layer (A) 14A is a layer in which a twisted rod-like liquid crystal compound having a helical axis in the thickness direction is immobilized. Therefore, as shown in FIGS. 2 and 3, the in-plane slow axis on the surface 141A of the optically anisotropic layer (A) 14A on the first optically anisotropic layer 12A side and the in-plane slow axis on the surface 142A of the optically anisotropic layer (B) 16A side form the above-described twisted angle (81° in FIG. 2). That is, an angle φa2 between the in-plane slow axis on the surface 141A of the optically anisotropic layer (A) 14A on the first optically anisotropic layer 12A side and the in-plane slow axis on the surface 142A of the optically anisotropic layer (B) 16A side is 81°. More specifically, the twisted direction of the rod-like liquid crystal compound in the optically anisotropic layer (A) 14A is a left-handed twist (counterclockwise), and the twisted angle thereof is 81°.

In FIGS. 2 and 3, the twisted angle of the rod-like liquid crystal compound in the optically anisotropic layer (A) 14A is 81°; but the present invention is not limited to this aspect, and the twisted angle of the rod-like liquid crystal compound is preferably within a range of 80°±30°, more preferably within a range of 80°±20°, and still more preferably within a range of 80°±10°.

As described above, in the aspect of FIG. 2 and FIG. 3, the in-plane slow axis of the first optically anisotropic layer 12A is rotated clockwise by 76°, and the twisted direction of the rod-like liquid crystal compound in the optically anisotropic layer (A) 14A is counterclockwise (left-handed twist), with reference to the absorption axis of the polarizer 30A, upon observation of the polarizing plate 100A from the polarizer 30A side.

In FIG. 2 and FIG. 3, the aspect in which the twisted direction of the rod-like liquid crystal compound is counterclockwise has been described in detail, but an aspect in which the twisted direction of the rod-like liquid crystal compound is clockwise may be configured as long as the relationship of the predetermined angle is satisfied. More specifically, an aspect in which the in-plane slow axis of the first optically anisotropic layer 12A is rotated counterclockwise by 76°, and the twisted direction of the rod-like liquid crystal compound in the optically anisotropic layer (A) 14A is clockwise (right-handed twist), with reference to the absorption axis of the polarizer 30A, upon observation of the polarizing plate 100A from the polarizer 30A side, may be used.

That is, in the polarizing plate 100A, in a case where the in-plane slow axis of the first optically anisotropic layer is rotated within a range of 40° to 85° (preferably 50° to 85° and more preferably 65° to) 85° clockwise with respect to the absorption axis of the polarizer 30A, it is preferable that the twisted direction of the rod-like liquid crystal compound in the optically anisotropic layer (A) is counterclockwise with respect to the in-plane slow axis on the surface of the optically anisotropic layer (A) on the first optically anisotropic layer side.

In addition, in the polarizing plate 100A, in a case where the in-plane slow axis of the first optically anisotropic layer is rotated within a range of 40° to 85° (preferably 50° to 85° and more preferably 65° to) 85° counterclockwise with respect to the absorption axis of the polarizer 30A, it is preferable that the twisted direction of the rod-like liquid crystal compound in the optically anisotropic layer (A) is clockwise with respect to the in-plane slow axis on the surface of the optically anisotropic layer (A) on the first optically anisotropic layer side.

The polarizing plate of the aspect 2 described above will be described with reference to FIGS. 4 to 6.

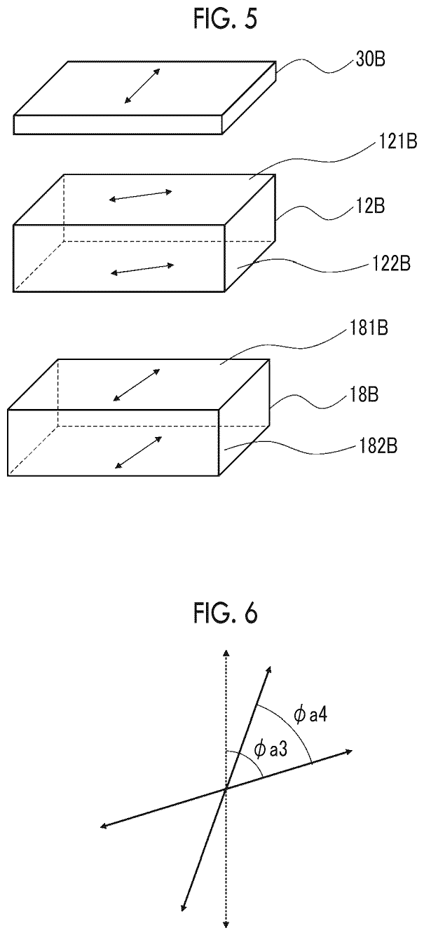

FIG. 4 is a schematic cross-sectional view of a polarizing plate 100B of the aspect 2. FIG. 5 is a view showing a relationship between an absorption axis of a polarizer 30B and in-plane slow axes of a first optically anisotropic layer 12B and an optically anisotropic layer (C) 18B in the polarizing plate 100B of the aspect 2 shown in FIG. 4. An arrow in the polarizer 30B in FIG. 5 represents the absorption axis, and arrows in the first optically anisotropic layer 12B and the optically anisotropic layer (C) 18B represent the in-plane slow axes in the layers, respectively.

FIG. 6 is a view showing a relationship between the absorption axis (broken line) of the polarizer 30B and the in-plane slow axes (solid lines) of the first optically anisotropic layer 12B and the optically anisotropic layer (C) 18B in a case of being observed from a white arrow side of FIG. 4. A rotation angle of the in-plane slow axes is represented by a positive angle value in a counterclockwise direction and a negative angle value in a clockwise direction, with respect to the absorption axis of the polarizer 30B (0°), upon observation from the white arrow side in FIG. 4.

As shown in FIG. 4, the polarizing plate 100B of the second aspect includes the polarizer 30B, the first optically anisotropic layer 12B, an intimate attachment layer 40B, and the optically anisotropic layer (C) 18B in this order. The polarizing plate 100B may include an intimate attachment layer (not shown) between the polarizer 30B and the first optically anisotropic layer 12B, or may include an optically anisotropic layer (for example, the third optically anisotropic layer) (not shown).

In the polarizing plate 100B of the second aspect, as shown in FIGS. 5 and 6, an angle φa3 between the absorption axis of the polarizer 30B and the first optically anisotropic layer 12B is 73°. More specifically, the in-plane slow axis of the first optically anisotropic layer 12B is rotated by −73° (73° clockwise) with respect to the absorption axis of the polarizer 30B. In FIGS. 5 and 6, φa3 is 73°; but the present invention is not limited to this aspect, and φa3 is preferably 40° to 85°, more preferably 50° to 85°, and still more preferably 65° to 85°.

In addition, as shown in FIG. 5, in the first optically anisotropic layer 12B, the in-plane slow axis on a surface 121B of the first optically anisotropic layer 12B on the polarizer 30B side is parallel to the in-plane slow axis on a surface 122B of the first optically anisotropic layer 12B on the optically anisotropic layer (C) 18B side.

As shown in FIGS. 5 and 6, an angle φa4 between the in-plane slow axis of the first optically anisotropic layer 12B and the in-plane slow axis of the optically anisotropic layer (C) 18B is 58°. More specifically, the in-plane slow axis of the optically anisotropic layer (C) 18B is rotated by 58° (58° counterclockwise) with respect to the in-plane slow axis of the first optically anisotropic layer 12B. In FIGS. 5 and 6, φa4 is 58°; but the present invention is not limited to this aspect, and φa4 is preferably 60°±30°, more preferably 60°±20°, and still more preferably 60°±10°.

In addition, as shown in FIG. 5, in the optically anisotropic layer (C) 18B, the in-plane slow axis on a surface 181B of the optically anisotropic layer (C) 18B on the first optically anisotropic layer 12B side is parallel to the in-plane slow axis on a surface 182B of the optically anisotropic layer (C) 18B on the side opposite to the first optically anisotropic layer 12B.

In FIGS. 4 to 6, the aspect in which the in-plane slow axis of the first optically anisotropic layer 12B is rotated within a range of 40° to 85° (preferably 50° to 85° and more preferably 65° to) 85° clockwise with respect to the absorption axis of the polarizer 30B in a case where the polarizing plate 100B is observed from the polarizer 30B side has been described, but the aspect in which the in-plane slow axis of the first optically anisotropic layer 12B is rotated within a range of 40° to 85° (preferably 50° to 85° and more preferably 65° to) 85° counterclockwise may be used. For example, in a case where the polarizing plate 100B is observed from the polarizer 30B side and the in-plane slow axis of the first optically anisotropic layer 12B is rotated within a range of 40° to 85° counterclockwise with respect to the absorption axis of the polarizer 30B, it is preferable that the in-plane slow axis of the optically anisotropic layer (C) 18B is rotated within a range of 60°±30° clockwise with respect to the in-plane slow axis of the first optically anisotropic layer 12B.

### [Manufacturing Method of Polarizing Plate]

A manufacturing method of the polarizing plate is not particularly limited, and a known method can be used.

For example, the polarizer and the optical film are each produced, and the polarizer and the optical film are bonded to each other through the intimate attachment layer in a predetermined direction to manufacture the polarizing plate.

A method of producing the above-described polarizer is as described above.

The intimate attachment layer for closely attaching the polarizer and the optical film is not particularly limited, and a known adhesive layer and a pressure-sensitive adhesive layer can be used; and for example, the intimate attachment layer described as the intimate attachment layer in the optical film above can be used.

The above-described optical film may be formed by laminating the first optically anisotropic layer, the intimate attachment layer, and the second optically anisotropic layer in this order, and a known method can be used.

For example, a method of producing each of the first optically anisotropic layer and the second optically anisotropic layer, and bonding the first optically anisotropic layer and the second optically anisotropic layer through the intimate attachment layer can be used. A method of bonding the first optically anisotropic layer and the second optically anisotropic layer through the intimate attachment layer is not particularly limited, and a known method can be used.

In a case where the above-described intimate attachment layer is an adhesive layer, it is preferable to perform a curing treatment on the adhesive layer after the bonding. A method of the curing treatment can be appropriately selected depending on the type of the adhesive layer, and examples thereof include a heating treatment and an active energy ray irradiation treatment.

Before forming and bonding the above-described intimate attachment layer, a surface treatment (for example, a glow discharge treatment, a corona discharge treatment, an ultraviolet (UV) treatment, or a flame treatment) may be performed on each optically anisotropic layer (for example, the first optically anisotropic layer and the second optically anisotropic layer) in order to improve adhesiveness.

The first optically anisotropic layer, the second optically anisotropic layer, and the third optically anisotropic layer described above can be produced, for example, using a composition for forming an optically anisotropic layer, containing a liquid crystal compound.

Hereinafter, a method of forming an optically anisotropic layer using a composition for forming an optically anisotropic layer will be described in detail.

### <Production Method of Optically Anisotropic Layer>

The optically anisotropic layer can be formed of a composition for forming an optically anisotropic layer.

### (Composition for Forming Optically Anisotropic Layer)

The liquid crystal compound contained in the composition for forming an optically anisotropic layer is the same as the liquid crystal compound contained in each of the optically anisotropic layers described above. As described above, a rod-like liquid crystal compound and a disk-like liquid crystal compound are appropriately selected according to the characteristics of the optically anisotropic layer to be formed.

As described above, the liquid crystal compound is preferably a polymerizable liquid crystal compound having a polymerizable group. The polymerizable group is as described above.

A content of the liquid crystal compound in the composition for forming an optically anisotropic layer is preferably 60% to 99% by mass and more preferably 70% to 98% by mass with respect to the total solid content of the composition for forming an optically anisotropic layer.

The solid content means a component capable of forming the optically anisotropic layer, excluding a solvent, and even in a case where a component itself is in a liquid state, such a component is regarded as the solid content.

The composition for forming an optically anisotropic layer may contain a compound other than the liquid crystal compound. Examples of other compounds include a chiral agent, a photo-alignment compound (photo-alignment polymer), a polymerization initiator, a polyfunctional monomer, an alignment control agent (vertical alignment agent or horizontal alignment agent), a surfactant, an adhesion improver, a plasticizer, and a solvent.

For example, the composition for forming an optically anisotropic layer, which is for forming the optically anisotropic layer (A), preferably contains a chiral agent in order to twist-align the liquid crystal compound. In a case where the liquid crystal compound is a compound exhibiting optical activity such as having an asymmetric carbon in the molecule, the addition of the chiral agent is not necessary. In addition, it is not necessary to add the chiral agent depending on the production method and the twisted angle.

The chiral agent is not particularly limited as long as it is compatible with the liquid crystal compound to be used in combination, and a known chiral agent can be used and appropriately selected depending on the desired helical sense and pitch.

As the chiral agent, for example, compounds described in Liquid Crystal Device Handbook, Chapter 3 articles 4-3, TN, chiral agent for STN, page 199, Japan Society for the Promotion of Science No. 142 committee version, 1989, and JP2003-287623A, JP2002-302487A, JP2002-080478A, JP2002-080851A, JP2010-181852A, and JP2014-034581A can be used.

Among these, as the chiral agent, a compound selected from the group consisting of an isosorbide derivative, an isomannide derivative, and a binaphthyl derivative is preferable. As the above-described isosorbide derivative, a commercially available product such as LC-756 manufactured by BASF may be used.

The chiral agent may have a polymerizable group. Examples of the polymerizable group which may be included in the chiral agent include the polymerizable group which may be included in the liquid crystal compound described above, and suitable aspects thereof are also the same.

A content of the chiral agent is preferably 0.01 to 200 mol % and more preferably 1 to 30 mol % with respect to the content of the liquid crystal compound.

The photo-alignment compound is a compound having a photo-aligned group, and the photo-aligned group can be aligned in a predetermined direction by irradiation with light.

The photo-alignment compound is preferably a photo-alignment polymer. The photo-alignment polymer is not particularly limited as long as it is compatible with the liquid crystal compound to be used in combination, and a known photo-alignment polymer can be used.

The composition for forming an optically anisotropic layer may contain a polymerization initiator. The polymerization initiator used is selected according to the type of polymerization reaction, and examples thereof include a thermal polymerization initiator and a photopolymerization initiator.

A content of the polymerization initiator in the composition for forming an optically anisotropic layer is preferably 0.01% to 20% by mass and more preferably 0.5% to 10% by mass with respect to the total solid content of the composition for forming an optically anisotropic layer.

### (Procedure for Forming Optically Anisotropic Layer)

A procedure for forming the optically anisotropic layer is not particularly limited, and examples thereof include a method of applying the above-described composition for forming an optically anisotropic layer onto a substrate, performing an alignment treatment on the formed coating film to align the liquid crystal compound, and then performing a curing treatment to immobilize the liquid crystal compound.

Examples of the above-described substrate include the substrate which may be included in the polarizing plate described above.

In addition, the optically anisotropic layer may be directly formed on the optically anisotropic layer using the composition for forming an optically anisotropic layer. That is, by applying the composition for forming an optically anisotropic layer onto the produced optically anisotropic layer, and then performing a predetermined treatment to form the optically anisotropic layer, a laminate in which two or more optically anisotropic layers are directly laminated without the intimate attachment layer can be produced. In a case where the optically anisotropic layer is directly formed on the optically anisotropic layer using the composition for forming an optically anisotropic layer, a treatment of forming an alignment film may be performed on the surface of the optically anisotropic layer before applying the composition for forming an optically anisotropic layer.

The applying method is not particularly limited, and examples thereof include an extrusion coating method, a curtain coating method, a dip coating method, a spin coating method, a printing coating method, a spray coating method, a slot coating method, a roll coating method, a slide coating method, a blade coating method, a gravure coating method, a die-coating method, and a wire bar coating method.

After the application of the composition for forming an optically anisotropic layer, a treatment of drying the coating film applied to the substrate may be performed as necessary. By the drying treatment, the solvent can be removed from the coating film.

A film thickness of the coating film is not particularly limited, but is preferably 0.1 to 20 μm, more preferably 0.2 to 15 μm, and still more preferably 0.5 to 10 μm.

The alignment treatment can be performed by drying the coating film at room temperature or by heating the coating film. In a case of a thermotropic liquid crystal compound, a liquid crystal phase formed by the alignment treatment can generally be transferred by a change in temperature or pressure. In a case of a lyotropic liquid crystal compound, a liquid crystal phase formed by the alignment treatment can also be transferred by a compositional ratio such as an amount of solvent.

Conditions in a case of heating the coating film are not particularly limited, and the heating temperature is preferably 50° C. to 250° C. and more preferably 50° C. to 150° C., and the heating time is preferably 10 seconds to 10 minutes.

In addition, after the coating film is heated, the coating film may be cooled as necessary, before a curing treatment (light irradiation treatment) described later. The cooling temperature is preferably 20° C. to 200° C. and more preferably 30° C. to 150° C.

The method of the curing treatment is not particularly limited, and examples thereof include a light irradiation treatment and a heating treatment. Among these, from the viewpoint of manufacturing suitability, a light irradiation treatment is preferable, and an ultraviolet irradiation treatment is more preferable.

Irradiation conditions of the light irradiation treatment are not particularly limited, and an irradiation amount of 50 to 1,000 mJ/cm² is preferable.

The atmosphere during the light irradiation treatment is not particularly limited, but is preferably a nitrogen atmosphere.

In a case where the composition for forming an optically anisotropic layer contains the photo-alignment polymer, it is preferable to perform a photo-alignment treatment from the viewpoint of imparting alignment control ability.

Examples of the photo-alignment treatment include a method of irradiating the coating film (including the cured film subjected to the curing treatment) of the composition for forming an optically anisotropic layer with polarized light, and a method of irradiating a surface of the coating film with non-polarized light from an oblique direction.

A wavelength of the polarized light or the unpolarized light is not particularly limited as long as the light is light to which the photo-aligned group is exposed. Examples thereof include ultraviolet rays, near-ultraviolet rays, and visible rays, and near-ultraviolet rays of 250 to 450 nm are preferable.

In addition, examples of a light source for the irradiation with polarized light or unpolarized light include a xenon lamp, a high-pressure mercury lamp, an ultra-high pressure mercury lamp, and a metal halide lamp. By using a dichroic filter, a color filter, or the like with respect to ultraviolet rays or visible rays obtained from the light source, the wavelength range of the irradiation can be restricted. In addition, linearly polarized light can be obtained by using a polarization filter or a polarization prism with respect to the light from the light source.

An integrated quantity of the polarized light or the unpolarized light is not particularly limited, but is preferably 1 to 300 mJ/cm² and more preferably 5 to 100 mJ/cm².

An illuminance of the polarized light or the unpolarized light is not particularly limited, but is preferably 0.1 to 300 mW/cm² and more preferably 1 to 100 mW/cm².

### [Applications]

The polarizing plate according to the embodiment of the present invention can be suitably applied to a display device.

The display device according to the embodiment of the present invention includes a display element and the polarizing plate according to the embodiment of the present invention.

The polarizing plate is usually provided on a visible side of the display device. In this case, in the polarizing plate, the polarizer is disposed on the visible side.

The display element is not particularly limited, and examples thereof include an organic electroluminescence display element (organic EL display element) and a liquid crystal display element.

The above-described organic electroluminescence display element is a member in which a light emitting layer or a plurality of organic compound thin films including a light emitting layer are formed between a pair of electrodes of an anode and a cathode, and may include a hole injection layer, a hole transport layer, an electron injection layer, an electron transport layer, and/or a protective layer in addition to the light emitting layer, and each of these layers may have other functions. Various materials can be used to form the respective layers.

Since the polarizing plate according to the embodiment of the present invention has a small thickness, it can be used for various applications having a curved surface, flexible applications, and foldable applications. In addition, since the polarizing plate according to the embodiment of the present invention has excellent durability and high degree of design freedom, it is also suitable for use in a vehicle. The organic EL display element exhibits a “burn-in” phenomenon due to deterioration of the element in a case of being displayed for a long time due to its characteristics. This is particularly problematic in a case of being used at a severe temperature, such as in a vehicle. The polarizing plate according to the embodiment of the present invention has excellent visibility from an oblique direction, has few defects and excellent display performance, and can reduce the visibility of display unevenness due to the burn-in of the display element, and thus can be suitably used not only for a small-sized display device such as a smartphone but also for a large-sized display device such as a monitor and a tablet which require a long lifetime.

### [Robustness Design of Tint Change]

A feature of the polarizing plate according to the embodiment of the present invention is that a tint change depending on the azimuthal angle is small (the change distance on the chromaticity diagram is small) in a case of being viewed from an oblique direction. On the other hand, in a case where the tint is changed in a part of the region due to a change in performance of the circularly polarizing plate by durability change, a change in another member of the display device (burn-in or the like), and a difference due to manufacturing variation, the tint change may be strongly visible as a change to a different quadrant on the chromaticity diagram. On the other hand, it is effective to set the tint to change within the same quadrant on the chromaticity diagram before and after the change, and it is possible to adopt it as a design having excellent robustness of the tint change.

### [Other Configurations]

It is also preferable to provide a hard coat layer, a cover glass, an ultra-thin glass, a hard film composed of a hard coat layer and a support, or the like on the surface of the polarizing plate according to the embodiment of the present invention opposite to the optically anisotropic layer (optical film) side, from the viewpoint of polarizing plate protection.

In addition, by providing a layer of low refractive index, or an AR layer in which a layer of high refractive index and a layer of low refractive index are alternately laminated on the surface of the hard coat layer and the glass on the visible side to reduce the reflectivity of the surface, the visibility can be further improved.

### EXAMPLES

Hereinafter, the present invention will be described in more detail with reference to Examples.

The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

### Example 1

### <Production of Cellulose Acylate Film (Substrate)>

The following composition (cellulose acylate dope) was put into a mixing tank and stirred, and further heated at 90° C. for 10 minutes. Thereafter, the obtained composition was filtered through a filter paper having an average hole diameter of 34 μm and a sintered metal filter having an average hole diameter of 10 μm to prepare a dope. The concentration of solid contents of the dope was 23.5% by mass, the amount of the plasticizer added was a proportion to cellulose acylate, and the solvent of the dope was methylene chloride/methanol/butanol=81/18/1 (mass ratio).

Cellulose acylate dope

| | |
|---|---|
| Cellulose acylate (acetyl substitution degree: 2.86, viscosity | 100 parts by mass |
| average degree of polymerization: 310) | |
| Compound 1 (shown as Formula (S4)) | 8.0 parts by mass |
| Compound 2 (shown as Formula (S5)) | 2.0 parts by mass |
| Compound 3 (shown as Formula (S6)) | 0.2 parts by mass |
| Compound 4 (shown as Formula (S7)) | 0.02 parts by mass |
| Silica particle dispersion (AEROSIL R972, | 0.1 parts by mass |
| manufactured by Nippon Aerosil Co., Ltd.) | |
| Solvent (methylene chloride/methanol/butanol) | |

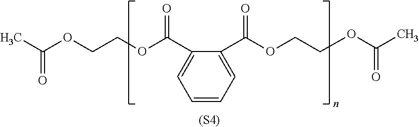

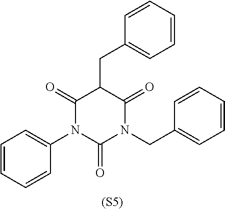

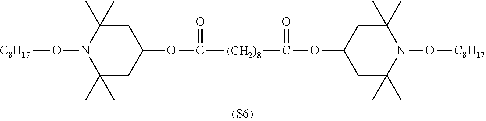

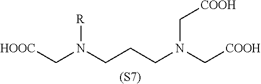

R = alkyl (C8~C24)

The dope produced above was cast using a band film forming machine. The dope was cast from a die such that it was in contact with a metal support, and then the obtained web (film) was stripped. The drum was made of SUS.

The web (film) obtained by casting was peeled off from the drum, and then dried in a tenter device for 20 minutes at 30° C. to 40° C. during film transport, and the tenter device transported the web by clipping both ends of the web. Subsequently, the web was post-dried by zone heating while being rolled. The obtained web was knurled and then wound up.

In the obtained cellulose acylate film, a film thickness was 40 μm, an in-plane retardation at a wavelength of 550 nm was 1 nm, and a thickness direction retardation at a wavelength of 550 nm was 26 nm.

### (Alkali Saponification Treatment)

After passing the cellulose acylate film obtained as described above through a dielectric heating roll at a temperature of 60° C. to raise the film surface temperature to 40° C., an alkaline solution having the composition shown below was applied onto a band surface of the film using a bar coater at a coating amount of 14 ml/m², followed by heating to 110° C., and transportation under a steam type far-infrared heater manufactured by Noritake Company Limited for 10 seconds. Subsequently, pure water was applied at 3 ml/m² using the same bar coater. Next, after repeating washing with water by a fountain coater and draining by an air knife three times, the film was transported to a drying zone at 70° C. for 10 seconds and dried to produce a cellulose acylate film subjected to an alkali saponification treatment.

Alkaline solution

| | | |
|---|---|---|
| Potassium hydroxide | 4.7 | parts by mass |
| Water | 15.8 | parts by mass |
| Isopropanol | 63.7 | parts by mass |
| Surfactant (C₁₄H₂₉O(CH₂CH₂O)₂₀H) | 1.0 | part by mass |
| Propylene glycol | 14.8 | parts by mass |

### <Formation of Alignment Film>

An alignment film coating liquid having the following formulation was continuously applied onto the surface of the cellulose acylate film which had been subjected to the alkali saponification treatment with a #14 wire bar. The film was further dried with hot air at 60° C. for 60 seconds and with hot air at 100° C. for 120 seconds.

Alignment film coating liquid

| | |
|---|---|
| Polyvinyl alcohol shown below | 10 parts by mass |
| Water | 371 parts by mass |
| Methanol | 119 parts by mass |
| Glutaraldehyde (crosslinking agent) | 0.5 parts by mass |
| Citric acid ester (manufactured by | 0.175 parts by mass |
| Sankyo Chemical Co., Ltd.) | |

Polyvinyl alcohol: polymerization degree of 300 (numerical value in each repeating unit represents a content (% by mass) with respect to all repeating units)

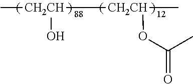

### <Formation of First Optically Anisotropic Layer>

The alignment film produced above was continuously subjected to a rubbing treatment. In this case, the longitudinal direction and the transport direction of the elongated film were parallel to each other, and an angle between the longitudinal direction (transport direction) of the film and the rotation axis of the rubbing roller was 76°. In a case where the longitudinal direction (transport direction) of the film was defined as 90° and the clockwise direction was represented by a positive value with reference to a width direction of the film as a reference (0°) in a case of being observed from the film side, the rotation axis of the rubbing roller was −14°. In other words, the position of the rotation axis of the rubbing roller is a position rotated by 76° counterclockwise with reference to the longitudinal direction of the film.

A composition (1a) for forming an optically anisotropic layer, containing a disk-like liquid crystal compound and having the following formulation, was applied onto the rubbing-treated alignment film using a Geeser coating machine to form a composition layer. Next, the obtained composition layer was heated with hot air at 110° C. for 2 minutes for drying of the solvent and alignment aging of the disk-like liquid crystal compound. Subsequently, the obtained composition layer was irradiated with UV (100 mJ/cm²) at 70° C. to fix the alignment of the liquid crystal compound to form an optically anisotropic layer (1a).

In the optically anisotropic layer (1a), a thickness was 1.6 μm, and an in-plane retardation at a wavelength of 550 nm was 168 nm. In addition, a value obtained by dividing the in-plane retardation at a wavelength of 550 nm by a thickness of the first optically anisotropic layer was 0.105. It was confirmed that an average tilt angle of a disc plane of the disk-like liquid crystal compound with respect to the film surface was 90°, and the disk-like liquid crystal compound was aligned perpendicular to the film surface. In addition, in a case of viewing from the optically anisotropic layer (1a) side, assuming that the slow axis angle of the optically anisotropic layer (1a) was parallel to the rotation axis of the rubbing roller, and the width direction of the film was 0° (the counterclockwise direction was 90° and the clockwise direction was −90° in the longitudinal direction), the slow axis was −14°.

The optically anisotropic layer (1a) corresponds to the first optically anisotropic layer.

Composition (1a) for forming optically anisotropic layer

| | |
|---|---|
| Disk-like liquid crystal compound 1 shown below | 80 parts by mass |
| Disk-like liquid crystal compound 2 shown below | 20 parts by mass |
| Alignment film interface alignment agent 1 shown below | 0.15 parts by mass |
| Fluorine-containing compound A shown below | 0.1 parts by mass |
| Fluorine-containing compound B shown below | 0.05 parts by mass |
| Fluorine-containing compound C shown below | 0.21 parts by mass |
| Ethylene oxide-modified trimethylolpropane triacrylate | 15 parts by mass |
| (V#360, manufactured by Osaka Organic Chemical Industry Ltd.) | |
| Photopolymerization initiator (APi-307, manufactured by Shenzhen | 6.0 parts by mass |
| UV ChemTech Ltd.) | |
| Methyl ethyl ketone | 200 parts by mass |

Disk-like liquid crystal compound 1 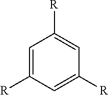 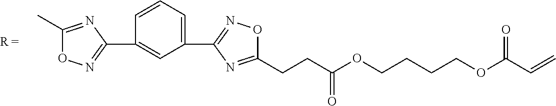 [SMILES: C=CC(=O)OCCCCOC(=O)CCc1nc(-c2cccc(-c3noc(C)n3)c2)no1]
Disk-like liquid crystal compound 2 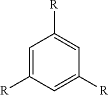 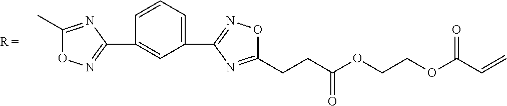 [SMILES: C=CC(=O)OCCOC(=O)CCc1nc(-c2cccc(-c3noc(C)n3)c2)no1]
Alignment film interface alignment agent 1 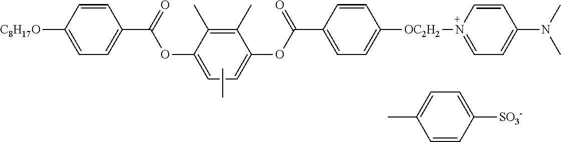
Fluorine-containing compound A (in the following formula, a and b represent the content (% by mass) of each repeating unit with respect to all repeating units, and a was 90% by mass and b was 10% by mass; a weight-average molecular weight thereof was 15,000) 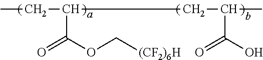
Fluorine-containing compound B (numerical value in each repeating unit represents the content with respect to all repeating units; a weight-average molecular weight thereof was 12,500) 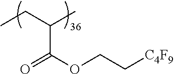 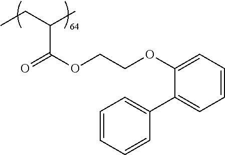
Fluorine-containing compound C (numerical value in each repeating unit represents the content with respect to all repeating units; a weight-average molecular weight thereof was 12,500) 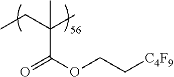 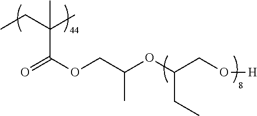
Photopolymerization initiator (APi-307, manufactured by Shenzhen UV ChemTech Ltd.)

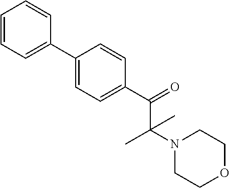 [SMILES: CC(C)(C(=O)c1ccc(-c2ccccc2)cc1)N1CCOCC1]

### <Formation of Second Optically Anisotropic Layer>

### (Formation of Optically Anisotropic Layer (B))

A composition (1c) for forming an optically anisotropic layer, containing a rod-like liquid crystal compound and having the following composition, was applied onto the cellulose acylate film produced above using a Geeser coating machine to form a composition layer. Thereafter, both ends of the film were held, a cooling plate (9° C.) was installed on the side of the surface on which the coating film of the film was formed so that the distance from the film was 5 mm, and a heater (75° C.) was installed on the side opposite to the surface on which the coating film of the film was formed so that the distance from the film was 5 mm, followed by drying for 2 minutes.

Next, the film was heated with hot air at 60° C. for 1 minute, and irradiated with ultraviolet rays having an irradiation amount of 100 mJ/cm² using a 365 nm UV-LED while purging with nitrogen so as to have an atmosphere having an oxygen concentration of 100 ppm or less. Thereafter, a precursor layer was formed by annealing with hot air at 120° C. for 1 minute.

The obtained precursor layer was irradiated with UV light (ultra-high pressure mercury lamp; UL750, manufactured by HOYA Corporation) passing through a wire grid polarizer at room temperature at an irradiation amount of 7.9 mJ/cm² (wavelength: 313 nm) to form a composition layer having an alignment control ability on the surface thereof.

The formed composition layer had a film thickness of 0.6 μm. An in-plane retardation at a wavelength of 550 nm was 0 nm, and a thickness direction retardation at a wavelength of 550 nm was-80 nm. It was confirmed that an average tilt angle of a major axis direction of the rod-like liquid crystal compound with respect to the film surface was 90° and the rod-like liquid crystal compound was aligned perpendicular to the film surface. The optically anisotropic layer (1c) corresponds to the optically anisotropic layer (B).

Composition (1c) for forming optically anisotropic layer

| | |
|---|---|
| Rod-like liquid crystal compound (A) shown below | 100 parts by mass |
| Polymerizable monomer (A-400, manufactured by Shin-Nakamura Chemical Co., Ltd.) | 4.0 parts by mass |
| Polymerization initiator S-1 (oxime type) shown below | 5.0 parts by mass |
| Photoacid generator D-1 shown below | 3.0 parts by mass |
| Polymer M-1 shown below | 2.0 parts by mass |
| Vertical alignment agent S01 shown below | 2.0 parts by mass |
| Photo-alignment polymer A-1 shown below | 2.0 parts by mass |
| Methyl ethyl ketone | 42.3 parts by mass |
| Methyl isobutyl ketone | 627.5 parts by mass |

Rod-like liquid crystal compound (A) (mixture of compounds shown below) 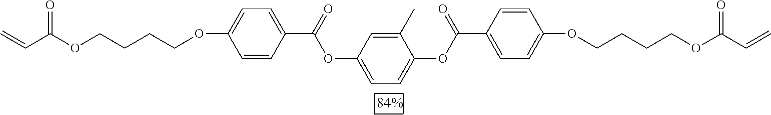 [SMILES: C=CC(=O)OCCCCOc1ccc(C(=O)Oc2ccc(OC(=O)c3ccc(OCCCCOC(=O)C=C)cc3)c(C)c2)cc1] 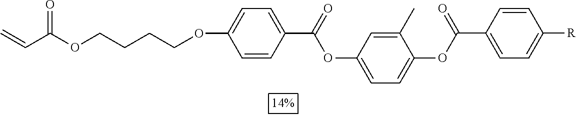 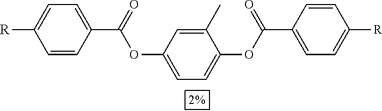 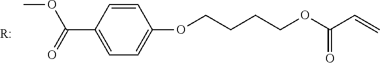
Polymerization initiator S-1 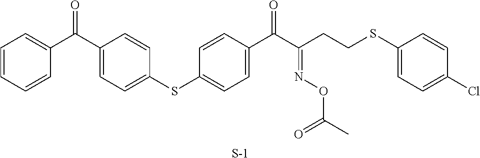
Photoacid generator D-1 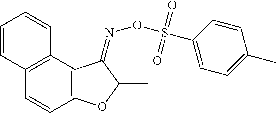 [SMILES: Cc1ccc(S(=O)(=O)O/N=C2/c3c(ccc4ccccc34)OC2C)cc1]
Polymer M-1 (numerical value in each repeating unit represents the content with respect to all repeating units; a weight-average molecular weight thereof was 58,000) 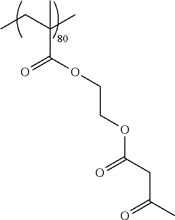 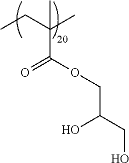
Vertical alignment agent S01 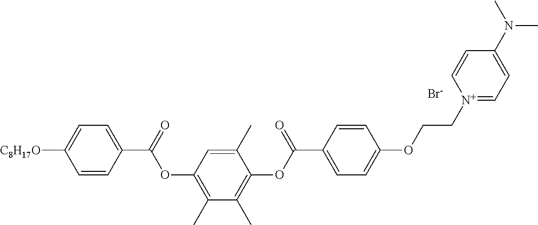
Photo-alignment polymer A-1 (in the following formula, a, b, and c represent the content (% by mass) of each repeating unit with respect to all repeating units, and a was 40% by mass, b was 25% by mass, and c was 35% by mass; a weight-average molecular weight thereof was 69,300)

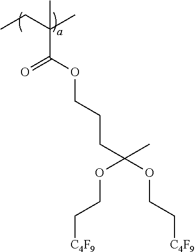

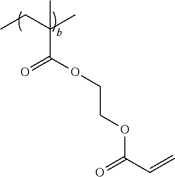

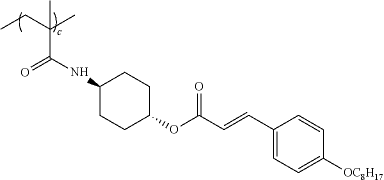

### (Formation of Optically Anisotropic Layer (A))

Next, a composition (1b) for forming an optically anisotropic layer, containing a rod-like liquid crystal compound and having the following composition, was applied onto the optically anisotropic layer (1c) produced as described above using a Geeser coating machine, and heated with hot air at 60° C. for 60 seconds. Subsequently, the obtained composition layer was irradiated with UV (300 mJ/cm²) at 80° C. to fix the alignment of the liquid crystal compound to form an optically anisotropic layer (1b).

In the optically anisotropic layer (1b), a thickness was 1.5 μm, And at a wavelength of 550 nm was 164 nm, and a twisted angle of the liquid crystal compound was 81°. Assuming that a width direction of the film is defined as 0° (a longitudinal direction of the film is defined as) 90°, the alignment axial angle of the liquid crystal compound was 14° on the air side and 95° on the side in contact with the optically anisotropic layer (1c), in a case of being viewed from the optically anisotropic layer (1b) side.

The alignment axial angle of the liquid crystal compound contained in the optically anisotropic layer is expressed as negative in a case where it is clockwise (right-handed turning) and positive in a case where it is counterclockwise (left-handed turning) with the width direction of the substrate as a reference of 0°, upon observing the substrate from the surface side of the optically anisotropic layer.

In addition, the twisted angle of the liquid crystal compound is expressed as negative in a case where the alignment axis direction of the liquid crystal compound on the substrate side (back side) is clockwise (right-handed turning) and positive in a case where it is counterclockwise (left-handed turning) with reference to the alignment axis direction of the liquid crystal compound on the surface side (front side), upon observing the substrate from the surface side of the optically anisotropic layer.

The optically anisotropic layer (1b) corresponds to the optically anisotropic layer (A).

Composition (1b) for forming optically anisotropic layer

| | |
|---|---|
| Rod-like liquid crystal compound (A) shown above | 70 parts by mass |
| Rod-like liquid crystal compound (B) shown below | 30 parts by mass |
| Ethylene oxide-modified trimethylolpropane triacrylate | 4 parts by mass |
| (V#360, manufactured by Osaka Organic Chemical Industry Ltd.) | |
| Photopolymerization initiator (Irgacure 819, manufactured by BASF SE) | 3 parts by mass |
| Left-twisted chiral agent (L1) shown below | 0.50 parts by mass |
| Fluorine-containing compound D shown below | 0.20 parts by mass |
| Methyl isobutyl ketone | 126 parts by mass |
| Ethyl propionate | 126 parts by mass |

Rod-like liquid crystal compound (B) 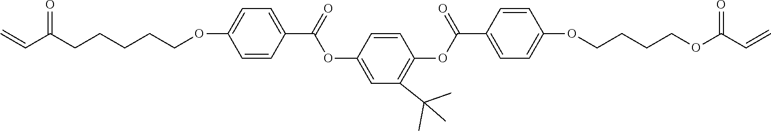 [SMILES: C=CC(=O)CCCCCOc1ccc(C(=O)Oc2ccc(OC(=O)c3ccc(OCCCCOC(=O)C=C)cc3)c(C(C)(C)C)c2)cc1]
Left-twisted chiral agent (L1) 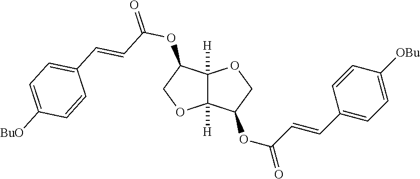
Fluorine-containing compound D (a content of the repeating unit on the left side was 76% by mass, a content of the repeating unit on the right side was 24% by mass, and a weight-average molecular weight thereof was 27,500)

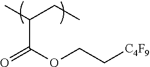

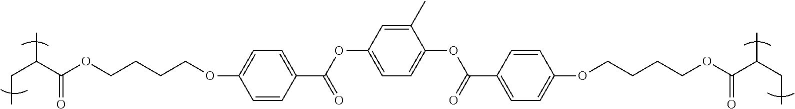

According to the above-described procedure, an optically anisotropic layer (1b-1c) in which the optically anisotropic layer (1c) and the optically anisotropic layer (1b) were directly laminated on the elongated cellulose acylate film was produced. In a case where a surface of the optically anisotropic layer (1c) on the side in contact with the optically anisotropic layer (1b) was confirmed, it was confirmed that the photo-alignment polymer was present.

The above-described optically anisotropic layer (1b-1c) corresponds to the optically anisotropic layer (AB).

### <Production of Optical Film>

A surface side of the optically anisotropic layer (1a) formed on the produced elongated cellulose acylate film was subjected to a corona discharge treatment. Conditions of the corona discharge treatment were set to an output intensity of 2.5 kW, a line speed of 18 m/min, an electrode length of 1.4 m, and a gap distance of 2 mm. The following ultraviolet curable adhesive (2a) was applied onto the treated surface subjected to the corona treatment such that the film thickness was 1.5 μm.

The surface side of the optically anisotropic layer (1b) in the optically anisotropic layer (1c-1b) formed on the produced elongated cellulose acylate film was also subjected to the corona discharge treatment. Conditions of the corona discharge treatment were set to an output intensity of 5.0 kW, a line speed of 18 m/min, an electrode length of 1.4 m, and a gap distance of 2 mm. The following adhesive (2a) was applied onto the treated surface subjected to the corona treatment such that the film thickness was 1.0 μm.

The adhesive (2a) applied onto the optically anisotropic layer (1a) and the adhesive (2a) applied onto the optically anisotropic layer (1b) were bonded to each other, heated to 50° C. using an IR heater, irradiated with UV light from both surfaces of the cellulose acylate film of the bonded laminate to cure the adhesive (2a), and then heat-dried at 70° C. for 3 minutes.

As a result, an optical film (1a-1b-1c) having a layer configuration of optically anisotropic layer (1a)—adhesive layer (2a)—optically anisotropic layer (1b-1c) was obtained. In the above-described optically anisotropic layer (1b-1c) of the optical film (1a-1b-1c), the optically anisotropic layer (1b) was disposed on the adhesive layer (2a) side.

An in-plane retardation of the above-described optical film (1a-1b-1c) at a wavelength of 550 nm was 141 nm.

Adhesive (2a)

| | | |
|---|---|---|
| Acryloyl morpholine (manufactured by | 40 | parts by mass |
| KOHJIN Co., Ltd.) | | |
| N-Hydroxyacrylamide (manufactured | 40 | parts by mass |
| by KOHJIN Co., Ltd.) | | |
| Tripropylene glycol diacrylate | 20 | parts by mass |
| (ARONIX M-220, manufactured by | | |
| TOAGOSEI CO., LTD.) | | |
| Photopolymerization initiator | 1.5 | parts by mass |
| (KAYACURE DETX-S, manufactured by | | |
| Nippon Kayaku Co., Ltd.) | | |

### <Production of Linear Polarizer>

A surface of a support of a cellulose triacetate film TJ25 (manufactured by Fujifilm Corporation; thickness: 25 μm) was subjected to an alkali saponification treatment. Specifically, the support was immersed in a 1.5 N sodium hydroxide aqueous solution at 55° C. for 2 minutes, washed in a water bath at room temperature, and further neutralized with a 0.1 N sulfuric acid at 30° C. After neutralization, the support was washed in a water bath at room temperature and further dried with hot air at 100° C. to obtain a polarizer protective film.

A roll-like polyvinyl alcohol (PVA) film having a thickness of 60 μm was continuously stretched in an iodine aqueous solution in a longitudinal direction, and dried to obtain a polarizer having a thickness of 13 μm. The luminosity corrected single transmittance of the polarizer was 43%. In this case, an absorption axis direction of the polarizer coincided with the longitudinal direction.

The above-described polarizer protective film was bonded to one surface of the above-described polarizer using the following PVA adhesive to produce a linear polarizer.

### (Preparation of PVA Adhesive)

100 parts by mass of a polyvinyl alcohol-based resin having an acetoacetyl group (average degree of polymerization: 1200, degree of saponification: 98.5 mol %, degree of acetoacetylation: 5 mol %) and 20 parts by mass of methylol melamine were dissolved in pure water under a temperature condition of 30° C. to prepare a PVA adhesive as an aqueous solution adjusted to a concentration of solid contents of 3.7% by mass.

### <Production of Polarizing Plate>

A surface of the optical film (1a-1b-1c) on which the surface of the optically anisotropic layer (1a) in contact with the cellulose acylate film was exposed was subjected to a corona discharge treatment. Conditions of the corona discharge treatment were set to an output intensity of 2.5 KW, a line speed of 18 m/min, an electrode length of 1.4 m, and a gap distance of 2 mm. The above-described adhesive (2a) was applied onto the treated surface subjected to the corona treatment such that the film thickness was 1.5 μm.

The surface of the produced elongated linear polarizer opposite to the polarizer protective film side and the surface of the above-described optical film (1a-1b-1c) on which the adhesive (2a) was applied were bonded to each other, and the adhesive (2a) was cured by the same method as described above to obtain a laminate of linear polarizer-optically anisotropic layer (1a)—adhesive layer (2a)—optically anisotropic layer (1b-1c).

Subsequently, the cellulose acylate film on the optically anisotropic layer (1b-1c) side was peeled off to expose the surface of the optically anisotropic layer (1b-1c) in contact with the cellulose acylate film. As a result, a polarizing plate (P1) including the optical film (1a-1b-1c) and the linear polarizer was produced. In the polarizing plate (P1), the polarizer protective film, the polarizer, the optically anisotropic layer (1a), the adhesive layer (2a), the optically anisotropic layer (1b), and the optically anisotropic layer (1c) were laminated in this order, and the polarizing plate (P1) corresponded to the polarizing plate of the aspect 1.

An angle between the absorption axis of the polarizer and the slow axis of the optically anisotropic layer (1a) was −76°. In addition, the alignment axial angle of the liquid crystal compound on the optically anisotropic layer (1a) side of the optically anisotropic layer (1b) was −14° with the width direction as a reference of 0°, which coincided with the slow axis direction of the optically anisotropic layer (1a).

### Example 2 and Examples 13 to 17

A polarizing plate was produced by the same method as in Example 1, except that, in the step of <Production of optical film>, an adhesive layer having a thickness and a thickness unevenness σ shown in Table 1 was formed by adjusting a component ratio of the adhesive (1a) and bonding conditions.

### Example 3

A polarizing plate was produced by the same method as in Example 1, except that an acrylic pressure-sensitive adhesive (NCF-D692, manufactured by LINTEC Corporation) (PSA) having a thickness of 5 μm was used instead of the adhesive (2a) used in Example 1.

### Example 4

A polarizing plate was produced by the same method as in Example 1, except that the following adhesive (2b) was used instead of the adhesive (2a) used in Example 1.

Adhesive (2b)

| | | |
|---|---|---|
| CEL2021P (Daicel Corporation) | 67 | parts by mass |
| 2-Ethylhexyl glycidyl ether (Tokyo | 10 | parts by mass |
| Chemical Industry Co., Ltd.) | | |
| RIKA RESIN DME100 (Shin-Nihon | 19 | parts by mass |
| Kagaku Kogyo Co., Ltd.) | | |
| CPI-100 (San-Apro Ltd.) | 4 | parts by mass |

### Examples 5 to 8, and Comparative Examples 1 and 2

A polarizing plate was produced by the same method as in Example 1, except that, in <Formation of first optically anisotropic layer> of Example 1, the amount of the ethylene oxide-modified trimethylolpropane triacrylate and the photopolymerization initiator (APi-307), and the temperature during the UV irradiation in the formation of the optically anisotropic layer were adjusted such that the value (Re/d) obtained by dividing the in-plane retardation of the first optically anisotropic layer at a wavelength of 550 nm by the thickness of the first optically anisotropic layer was a value shown in Table 1.

### Examples 9 and 10

A polarizing plate was produced by the same method as in Example 1, except that, in <Formation of first optically anisotropic layer> of Example 1, the value (Re/d) obtained by dividing the in-plane retardation of the first optically anisotropic layer at a wavelength of 550 nm by the thickness of the first optically anisotropic layer was adjusted by adjusting the film thickness of the optically anisotropic layer to be a value shown in Table 1.

### Example 11

### <Formation of First Optically Anisotropic Layer>

As in the above-described optically anisotropic layer (1a), the alignment film applied onto the cellulose acylate film was continuously subjected to a rubbing treatment. In this case, the longitudinal direction and the transport direction of the elongated film were parallel to each other, and an angle between the longitudinal direction (transport direction) of the film and the rotation axis of the rubbing roller was 73°. In a case where the longitudinal direction (transport direction) of the film was defined as 90° and the clockwise direction was represented by a positive value with reference to a width direction of the film as a reference (0°) in a case of being observed from the film side, the rotation axis of the rubbing roller was −17°. In other words, the position of the rotation axis of the rubbing roller was a position rotated by 73° counterclockwise with reference to the longitudinal direction of the film.

A composition (li) for forming an optically anisotropic layer, containing a disk-like liquid crystal compound and having the following formulation, was applied onto the rubbing-treated alignment film using a Geeser coating machine to form a composition layer. Next, the obtained composition layer was heated with hot air at 110° C. for 2 minutes for drying of the solvent and alignment aging of the disk-like liquid crystal compound. Subsequently, the obtained composition layer was irradiated with UV (70 mJ/cm²) at 80° C. to fix the alignment of the liquid crystal compound to form an optically anisotropic layer (li).

A thickness of the optically anisotropic layer (li) was 2.2 μm. In addition, an in-plane retardation at a wavelength of 550 nm was 236 nm. It was confirmed that an average tilt angle of a disc plane of the disk-like liquid crystal compound with respect to the film surface was 90°, and the disk-like liquid crystal compound was aligned perpendicular to the film surface. In addition, in a case of viewing from the optically anisotropic layer (li) side, assuming that the slow axis angle of the optically anisotropic layer (li) was parallel to the rotation axis of the rubbing roller, and the width direction of the film was 0° (the counterclockwise direction was 90° and the clockwise direction was −90° in the longitudinal direction), the slow axis was −17°.

The optically anisotropic layer (li) corresponds to the first optically anisotropic layer.

Composition (li) for forming optically anisotropic layer

| | | |
|---|---|---|
| Disk-like liquid crystal compound 1 shown above | 80 | parts by mass |
| Disk-like liquid crystal compound 2 shown above | 20 | parts by mass |
| Alignment film interface alignment agent 1 | 0.10 | parts by mass |
| shown above | | |
| Fluorine-containing compound A shown above | 0.1 | parts by mass |
| Fluorine-containing compound B shown above | 0.05 | parts by mass |
| Fluorine-containing compound C shown above | 0.21 | parts by mass |
| Ethylene oxide-modified trimethylolpropane | 13 | parts by mass |
| triacrylate | | |
| (V#360, manufactured by Osaka Organic | | |
| Chemical Industry Ltd.) | | |
| Photopolymerization initiator (IRGACURE | 5.0 | parts by mass |
| 907, manufactured by BASF) | | |
| Methyl ethyl ketone | 200 | parts by mass |

### <Formation of Second Optically Anisotropic Layer>

The alignment film produced in Example 1 was continuously subjected to a rubbing treatment. In this case, the longitudinal direction and the transport direction of the elongated film were parallel to each other, and an angle between the longitudinal direction (transport direction) of the film and the rotation axis of the rubbing roller was 105°. In a case where the longitudinal direction (transport direction) of the film was defined as 90° and the clockwise direction was represented by a positive value with reference to a width direction of the film as a reference (0°) in a case of being observed from the film side, the rotation axis of the rubbing roller was 75°. In other words, the position of the rotation axis of the rubbing roller was a position rotated by 105° counterclockwise with reference to the longitudinal direction of the film.

A composition (1j) for forming an optically anisotropic layer, containing a disk-like liquid crystal compound and having the following formulation, was applied onto the rubbing-treated alignment film using a Geeser coating machine to form a composition layer. Next, the obtained composition layer was heated with hot air at 60° C. for 2 minutes for drying of the solvent and alignment aging of the disk-like liquid crystal compound. Subsequently, the obtained composition layer was irradiated with UV (70 mJ/cm²) at 60° C. to fix the alignment of the liquid crystal compound to form an optically anisotropic layer (1j).

A thickness of the optically anisotropic layer (1j) was 1.1 μm. In addition, an in-plane retardation at a wavelength of 550 nm was 116 nm. It was confirmed that an average tilt angle of a disc plane of the disk-like liquid crystal compound with respect to the film surface was 90°, and the disk-like liquid crystal compound was aligned perpendicular to the film surface. In addition, in a case of viewing from the optically anisotropic layer (1j) side, assuming that the slow axis angle of the optically anisotropic layer (1j) was parallel to the rotation axis of the rubbing roller, and the width direction of the film was 0° (the counterclockwise direction was 90° and the clockwise direction was −90° in the longitudinal direction), the slow axis was 75°.

The optically anisotropic layer (1j) corresponds to the optically anisotropic layer (C).

Composition (1j) for forming optically anisotropic layer

| | | |
|---|---|---|
| Disk-like liquid crystal compound 1 shown above | 80 | parts by mass |
| Disk-like liquid crystal compound 2 shown above | 20 | parts by mass |
| Alignment film interface alignment agent 1 | 0.30 | parts by mass |
| shown above | | |
| Fluorine-containing compound A shown above | 0.1 | parts by mass |
| Fluorine-containing compound B shown above | 0.05 | parts by mass |
| Fluorine-containing compound C shown above | 0.21 | parts by mass |
| Ethylene oxide-modified trimethylolpropane | 10 | parts by mass |
| triacrylate | | |
| (V#360, manufactured by Osaka Organic | | |
| Chemical Industry Ltd.) | | |
| Photopolymerization initiator (IRGACURE | 3.0 | parts by mass |
| 907, manufactured by BASF) | | |
| Methyl ethyl ketone | 200 | parts by mass |

### <Production of Polarizing Plate (P11)>

Using the obtained optically anisotropic layer (li) and the optically anisotropic layer (1j), an optical film (1i-1j) in which the optically anisotropic layer (li), the adhesive layer (2a), and the optically anisotropic layer (1j) were laminated in this order was obtained by the same method as in Example 1.

Next, a polarizing plate (P11) including the optical film (1i-1j) and the linear polarizer was produced by the same method as in Example 1.

In the polarizing plate (P11), the polarizer protective film, the polarizer, the optically anisotropic layer (li), the adhesive layer (2a), and the optically anisotropic layer (1j) were laminated in this order, and the polarizing plate (P11) corresponded to the polarizing plate of the aspect 2.

An angle between the absorption axis of the polarizer and the slow axis of the optically anisotropic layer (li) was −73°. In addition, an angle between the slow axis of the optically anisotropic layer (li) and the slow axis of the optically anisotropic layer (1j) was 58°.

### Example 12

### <Formation of First Optically Anisotropic Layer>

As in the optically anisotropic layer (1a), the alignment film applied onto the cellulose acylate film was continuously subjected to a rubbing treatment. In this case, the longitudinal direction and the transport direction of the elongated film were parallel to each other, and an angle between the longitudinal direction (transport direction) of the film and the rotation axis of the rubbing roller was 75°. In a case where the longitudinal direction (transport direction) of the film was defined as 90° and the clockwise direction was represented by a positive value with reference to a width direction of the film as a reference (0°) in a case of being observed from the film side, the rotation axis of the rubbing roller was −15°. In other words, the position of the rotation axis of the rubbing roller was a position rotated by 75° counterclockwise with reference to the longitudinal direction of the film.

A composition (1k) for forming an optically anisotropic layer, containing a rod-like liquid crystal compound and having the following formulation, was applied onto the rubbing-treated alignment film using a Geeser coating machine to form a composition layer. Next, the obtained composition layer was heated with hot air at 110° C. for 2 minutes for drying of the solvent and alignment aging of the rod-like liquid crystal compound. Subsequently, the obtained composition layer was irradiated with UV (100 mJ/cm²) at 90° C. to fix the alignment of the liquid crystal compound to form an optically anisotropic layer (1k).

A thickness of the optically anisotropic layer (1k) was 2.0 μm. In addition, an in-plane retardation at a wavelength of 550 nm was 220 nm. It was confirmed that an average tilt angle of the rod-like liquid crystal compound with respect to the film surface was 0°, and the rod-like liquid crystal compound was horizontally aligned with respect to the film surface. In addition, in a case of viewing from the optically anisotropic layer (1k) side, assuming that the slow axis angle of the optically anisotropic layer (1k) was parallel to the rotation axis of the rubbing roller, and the width direction of the film was 0° (the counterclockwise direction was 90° and the clockwise direction was −90° in the longitudinal direction), the slow axis was −15°.

The optically anisotropic layer (1k) corresponds to the first optically anisotropic layer.

Composition (1k) for forming optically anisotropic layer

| | | |
|---|---|---|
| Rod-like liquid crystal compound (A) | 80 | parts by mass |
| shown above | | |
| Rod-like liquid crystal compound (B) | 20 | parts by mass |
| shown above | | |
| Ethylene oxide-modified trimethylolpropane | 10 | parts by mass |
| triacrylate | | |
| (V#360, manufactured by Osaka Organic | | |
| Chemical Industry Ltd.) | | |
| Photopolymerization initiator (Irgacure | 3 | parts by mass |
| 907, manufactured by BASF SE) | | |
| Fluorine-containing compound D shown | 0.20 | parts by mass |
| above | | |
| Methyl ethyl ketone | 250 | parts by mass |

### <Production of Polarizing Plate (P12)>

Using the obtained optically anisotropic layer (1k) and the optically anisotropic layer (1j) obtained in Example 11, an optical film (1k-1j) in which the optically anisotropic layer (1k), the adhesive layer (2a), and the optically anisotropic layer (1j) were laminated in this order was obtained by the same method as in Example 1.

Next, a polarizing plate (P12) including the optical film (1k-1j) and the linear polarizer was produced by the same method as in Example 1.

In the polarizing plate (P12), the polarizer protective film, the polarizer, the optically anisotropic layer (1k), the adhesive layer (2a), and the optically anisotropic layer (1j) were laminated in this order, and the polarizing plate (P12) corresponded to the polarizing plate of the aspect 2.

An angle between the absorption axis of the polarizer and the slow axis of the optically anisotropic layer (1k) was −75°. In addition, an angle between the slow axis of the optically anisotropic layer (1k) and the slow axis of the optically anisotropic layer (1j) was 15°.

### Example 18

A polarizing plate was produced by the same method as in Example 2, except that, in the step of <Formation of first optically anisotropic layer>, the composition (1a) for forming an optically anisotropic layer was changed to the following composition (11) for forming an optically anisotropic layer; and in the step of <Formation of second optically anisotropic layer>, the composition (1b) for forming an optically anisotropic layer was changed to the following composition (1m) for forming an optically anisotropic layer, and the composition (1c) for forming an optically anisotropic layer was changed to the following composition (In) for forming an optically anisotropic layer.

Composition (11) for forming optically anisotropic layer

| | |
|---|---|
| Disk-like liquid crystal compound 1 shown above | 80 parts by mass |
| Disk-like liquid crystal compound 2 shown above | 20 parts by mass |
| Alignment film interface alignment agent 1 shown above | 1.0 part by mass |
| Silicon-containing compound A shown below | 0.1 parts by mass |
| Ethylene oxide-modified trimethylolpropane triacrylate | 13 parts by mass |
| (V#360, manufactured by Osaka Organic Chemical Industry Ltd.) | |
| Photopolymerization initiator (APi-307, manufactured by Shenzhen UV ChemTech Ltd.) | 6.0 parts by mass |
| Methyl ethyl ketone | 200 parts by mass |

Silicon-containing compound A (in the following formula, a, b, c, and d represent the content (mol %) of each repeating unit with respect to all repeating units, and a was 78 mol %, b was 10 mol %, c was 1 mol %, and d was 11 mol %; a weight-average molecular weight thereof was 13,500)

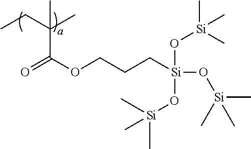

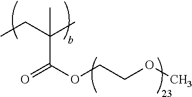

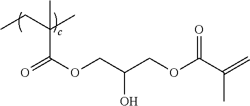

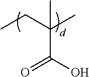

Composition (1m) for forming optically anisotropic layer

| | |
|---|---|
| Rod-like liquid crystal compound (A) shown above | 70 parts by mass |
| Rod-like liquid crystal compound (B) shown above | 30 parts by mass |
| Ethylene oxide-modified trimethylolpropane triacrylate | 4 parts by mass |
| (V#360, manufactured by Osaka Organic Chemical Industry Ltd.) | |
| Photopolymerization initiator (Irgacure 819, manufactured by BASF SE) | 3 parts by mass |
| Left-handed twisting chiral agent (L1) shown above | 0.50 parts by mass |
| Silicon-containing compound B shown below | 0.15 parts by mass |
| Methyl isobutyl ketone | 126 parts by mass |
| Ethyl propionate | 126 parts by mass |

Silicon-containing compound B (in the following formula, a, b, and c represent the content (% by mass) of each repeating unit with respect to all repeating units, and a was 56% by mass, b was 36% by mass, and c was 8% by mass; a weight-average molecular weight thereof was 17,000)

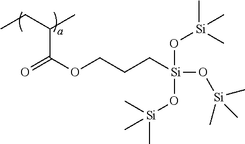

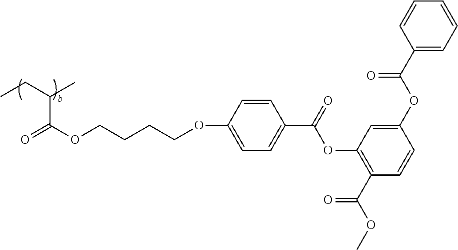

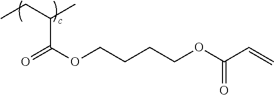

Composition (1n) for forming optically anisotropic layer

| | |
|---|---|
| Rod-like liquid crystal compound (A) shown above | 100 parts by mass |
| Polymerizable monomer (A-400, manufactured by Shin-Nakamura Chemical Co., Ltd.) | 4.0 parts by mass |
| Polymerization initiator S-1 (oxime type) shown above | 5.0 parts by mass |
| Photoacid generator D-1 shown above | 4.5 parts by mass |
| Polymer M-1 shown above | 2.0 parts by mass |
| Vertical alignment agent S01 shown above | 1.5 parts by mass |
| Vertical alignment agent S02 shown below | 0.5 parts by mass |
| Photo-alignment polymer A-2 shown below | 1.0 part by mass |
| Methyl ethyl ketone | 42.3 parts by mass |
| Methyl isobutyl ketone | 627.5 parts by mass |

Vertical alignment agent S02 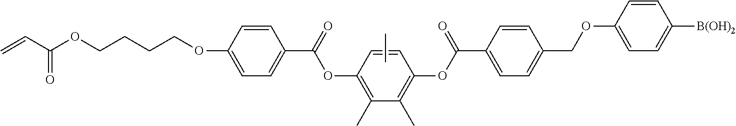
Photo-alignment polymer A-2 (in the following formula, a, b, and c represent the content (% by mass) of each repeating unit with respect to all repeating units, and a was 34% by mass, b was 26% by mass, and c was 40% by mass; a weight-average molecular weight thereof was 100,000; Me represents a methyl group)

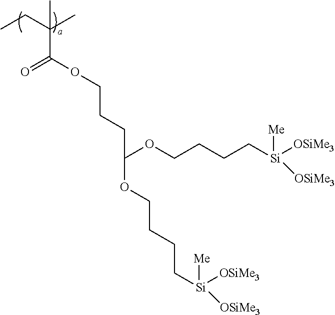

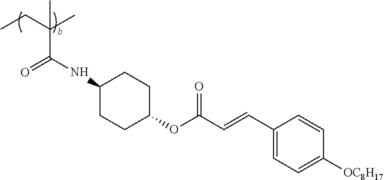

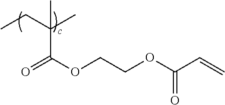

### Example 19

A polarizing plate was produced by the same method as in Example 18, except that the steps of <Production of cellulose acylate film (substrate)> and <Formation of alignment film> were changed as follows; and in the step of <Formation of first optically anisotropic layer>, the composition (11) for forming an optically anisotropic layer was changed to the following composition (10) for forming an optically anisotropic layer, and the temperature during the UV irradiation in the formation of the optically anisotropic layer were adjusted such that the value (Re/d) obtained by dividing the in-plane retardation of the first optically anisotropic layer at a wavelength of 550 nm by the thickness of the first optically anisotropic layer was a value shown in Table 1.

### <Production of Cellulose Acylate Film 1 (Substrate)>

### (Production of Core Layer Cellulose Acylate Dope)

The following composition was put into a mixing tank and stirred to dissolve each component, thereby preparing a cellulose acetate solution used as a core layer cellulose acylate dope.

Core layer cellulose acylate dope

| | |
|---|---|
| Cellulose acetate having acetyl | 100 parts by mass |
| substitution degree of 2.88 | |
| Polyester compound B described in | 8 parts by mass |
| Examples of JP2015-227955A | |
| The following compound G | 4 parts by mass |
| Methylene chloride (first solvent) | 430 parts by mass |
| Methanol (second solvent) | 64 parts by mass |

Compound G

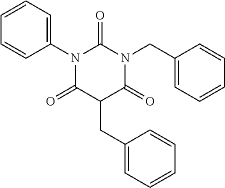 [SMILES: O=C1C(Cc2ccccc2)C(=O)N(c2ccccc2)C(=O)N1Cc1ccccc1]

### (Production of Outer Layer Cellulose Acylate Dope)

10 parts by mass of the following matting agent solution was added to 90 parts by mass of the core layer cellulose acylate dope to prepare a cellulose acetate solution to be used as an outer layer cellulose acylate dope.

Matting agent solution

| | | |
|---|---|---|
| Silica particles with average particle size of | 2 | parts by mass |
| 20 nm | | |
| (AEROSIL R972, manufactured by Nippon | | |
| Aerosil Co., Ltd.) | | |
| Methylene chloride (first solvent) | 76 | parts by mass |
| Methanol (second solvent) | 11 | parts by mass |
| Core layer cellulose acylate dope | 1 | part by mass |
| described above | | |

The core layer cellulose acylate dope and the outer layer cellulose acylate dope were filtered through filter paper having an average hole diameter of 34 μm and a sintered metal filter having an average pore size of 10 μm, and three layers which were the core layer cellulose acylate dope and the outer layer cellulose acylate dopes provided on both sides of the core layer cellulose acylate dope were simultaneously cast from a casting port onto a drum at 20° C., using a band casting machine.

The film was peeled off in a state in which the solvent content was approximately 20% by mass, both ends of the film in the width direction were fixed by tenter clips, and the film was dried while being stretched at a stretching ratio of 1.1 times in the lateral direction. Thereafter, the film was transported between rolls in a heating treatment device, and further dried to produce an optical film having a thickness of 40 μm, which was regarded as a cellulose acylate film 1.

The obtained cellulose acylate film 1 had an in-plane retardation of 0 nm at a wavelength of 550 nm. The obtained cellulose acylate film 1 was used as a substrate.

### <Formation of Alignment Film>

An air surface of the cellulose acylate film 1 was continuously coated with the composition 1 for forming a photo-alignment film using a geeser coating machine to form a coating film. Next, the coating film was dried in a heating zone at 130° C. for 1 minute to remove the solvent, thereby forming a cured film having a thickness of 0.7 μm.

Next, the cured film was irradiated with ultraviolet rays (10 mJ/cm², light source: ultra-high pressure mercury lamp, measurement wavelength: 313 nm) through a wire grid polarizer to form a photo-alignment film PA-1. In this case, a transmission axis of the wire grid polarizer was set to an angle of 14° with respect to a longitudinal direction of the film.

Composition 1 for forming photo-alignment film

| | |
|---|---|
| Photo-alignment polymer P-1 shown below | 4.0 parts by mass |
| Epoxy compound E-1 shown below | 96.0 parts by mass |
| Thermal acid generator B shown below | 6.0 parts by mass |
| Diisopropylethylamine | 0.6 parts by mass |
| Butyl acetate | 594.0 parts by mass |
| Methyl ethyl ketone | 306.0 parts by mass |

Photo-alignment polymer P-1 [number attached to each repeating unit: mass ratio of each unit to all repeating units; weight-average molecular weight: 55,000] 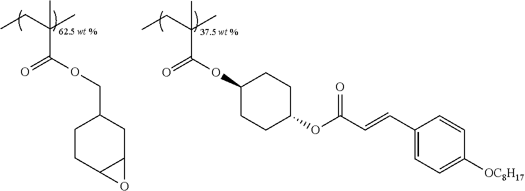
Epoxy compound E-1 [number attached to each repeating unit: mass ratio of each unit to all repeating units; weight-average molecular weight: 45,000] 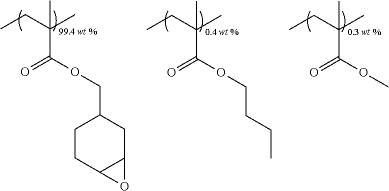
Thermal acid generator B

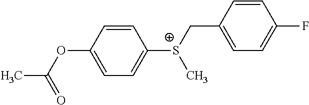 [SMILES: CC(=O)Oc1ccc([S+](C)Cc2ccc(F)cc2)cc1]

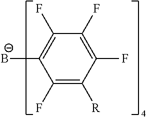

Composition (1o) for forming optically anisotropic layer

| | | |
|---|---|---|
| Disk-like liquid crystal compound 1 shown above | 80 | parts by mass |
| Disk-like liquid crystal compound 2 shown above | 20 | parts by mass |
| Alignment film interface alignment agent 1 | 1.0 | part by mass |
| shown above | | |
| Silicon-containing compound A shown | 0.2 | parts by mass |
| above | | |
| Ethylene oxide-modified trimethylolpropane | 5 | parts by mass |
| triacrylate | | |
| (V#360, manufactured by Osaka Organic | | |
| Chemical Industry Ltd.) | | |
| Photopolymerization initiator (APi-307, | 4.0 | parts by mass |
| manufactured by Shenzhen UV ChemTech | | |
| Methyl ethyl ketone | 200 | parts by mass |

### [Evaluation]

An organic EL display device was produced using the polarizing plate of each of Examples and Comparative Examples, produced by the above-described method, and the following evaluations were performed.

### [Production of Organic EL Display Device]

An organic EL panel-equipped GALAXY S4 manufactured by SAMSUNG Electronics Co., Ltd. was disassembled, a circularly polarizing plate was peeled off, and the polarizing plate produced as described above was bonded to the display device using a pressure-sensitive adhesive such that the polarizer protective film was disposed on the outer side.

### [Evaluation of Display Performance]

### <Front Tint>

The produced organic EL display device was set to a black display state, and observed from a front direction in a bright light to evaluate a tint change according to the following evaluation standard. The results are shown in Table 2.
A: tinting was not visible at all, or the tinting was visible, but only a little (acceptable).
B: tinting was slightly visible, but there was no problem in use (acceptable).
C: tinting was visible, but there was no problem in use (acceptable).
D: tinting was strongly visible, which was not acceptable.

### <Tint Azimuthal Angle Dependence>

The produced organic EL display device was set to a black display state, a fluorescent lamp was projected from a polar angle of 45° under bright light, and the reflected light was observed from all orientations. As a result, the tint azimuthal angle dependence in a case of being viewed from an oblique direction was evaluated according to the following standard. The results are shown in Table 2.
A: no tint difference due to the azimuthal angle was visible (acceptable).
B: tint difference due to the azimuthal angle was very slightly visible, but there was no problem in use (acceptable).
C: tint difference due to the azimuthal angle was slightly visible, but there was no problem in use (acceptable).
D: tint difference due to the azimuthal angle was visible, which was not acceptable.

### <In-Plane Tint Unevenness>

The produced polarizing plate was bonded to a black acrylic plate (ACRYLITE L502 Black, manufactured by Mitsubishi Chemical Corporation) using a pressure-sensitive adhesive such that the polarizer protective film was disposed on the outer side. A diffusion plate was set to an azimuthal angle at which the major axis direction of the rod-shaped fluorescent lamp and the longitudinal direction of the polarizing plate were orthogonal to each other under a rod-shaped fluorescent lamp (FPL-27EX-N), and an in-plane tint was observed from a polar angle of 30° to 40°. As a result, the in-plane tint unevenness in a case of being viewed from an oblique direction was evaluated according to the following standard. The results are shown in Table 2.
A: in-plane tint unevenness was not visible at all, or the in-plane tint unevenness was visible, but only a little (acceptable).
B: in-plane tint unevenness was slightly visible, but there was no problem in use (acceptable).
C: in-plane tint unevenness was visible, but there was no problem in use (acceptable).
D: in-plane tint unevenness was visible, which was not acceptable.

### [Air Bubbles During Bonding]

The produced organic EL display device was set to a black display state, and observed from a front direction and a 20° direction in a bright light to evaluate defects due to air bubbles according to the following standard. The results are shown in Table 2.

No air bubbles: no defects were observed by visual inspection, and there was no problem in use (acceptable).

Air bubbles: clear trace of color loss in a circular shape was present, which was not acceptable.

### [Result]

The configuration and evaluation results of the polarizing plate of each of Examples and Comparative Examples are shown in Tables 1 and 2. Table 2 is a continuation of Table 1. For example, the optical film of Example 1 included the first optically anisotropic layer and the intimate attachment layer shown in Table 1 and the second optically anisotropic layer shown in Table 2, and had an in-plane retardation of 141 nm at a wavelength of 550 nm.

In Table 1, Re/d indicates the value obtained by dividing the in-plane retardation Re of the first optically anisotropic layer at a wavelength of 550 nm by the thickness d of the first optically anisotropic layer.

In Tables 1 and 2, in a case where the optically anisotropic layer consisted of two layers, the optically anisotropic layer is indicated as “optically anisotropic layer on polarizer side/optically anisotropic layer on side opposite to polarizer side”. For example, as in Example 1, in a case where the column of liquid crystal type of the second optically anisotropic layer is “Rod-like/rod-like” and the column of alignment state of the liquid crystal is “Twisted/vertical”, it means that the second optically anisotropic layer was a laminate of a layer in which a twisted rod-like liquid crystal compound was immobilized and a layer in which a vertically aligned rod-like liquid crystal compound was immobilized, from the polarizer side.

TABLE 1

| | First optically anisotropic layer | | | | | | Intimate attachment layer | | | |
|---|---|---|---|---|---|---|---|---|---|---|
| | Type of | | | Film | | Average | Closely | Film | Thickness | Average |
| | liquid | Alignment state | Re | thickness | | refractive | attaching | thickness | unevenness σ | refractive |
| | crystal | of liquid crystal | (nm) | (μm) | Re/d | index | agent | (μm) | (nm) | index |
| Example 1 | Disk-like | Perpendicular | 168 | 1.6 | 0.105 | 1.57 | Adhesive (2a) | 2.5 | 5 | 1.52 |
| Example 2 | Disk-like | Perpendicular | 168 | 1.6 | 0.105 | 1.57 | Adhesive (2a) | 2.5 | 10 | 1.52 |
| Example 3 | Disk-like | Perpendicular | 168 | 1.6 | 0.105 | 1.57 | PSA | 5 | 7 | 1.48 |
| Example 4 | Disk-like | Perpendicular | 168 | 1.6 | 0.105 | 1.57 | Adhesive (2b) | 3 | 12 | 1.51 |
| Example 5 | Disk-like | Perpendicular | 168 | 1.8 | 0.093 | 1.57 | Adhesive (2a) | 2.5 | 10 | 1.52 |
| Example 6 | Disk-like | Perpendicular | 168 | 2.0 | 0.084 | 1.57 | Adhesive (2a) | 2.5 | 10 | 1.52 |
| Example 7 | Disk-like | Perpendicular | 168 | 2.2 | 0.076 | 1.57 | Adhesive (2a) | 2.5 | 10 | 1.52 |
| Example 8 | Disk-like | Perpendicular | 168 | 1.5 | 0.116 | 1.57 | Adhesive (2a) | 2.5 | 10 | 1.52 |
| Example 9 | Disk-like | Perpendicular | 150 | 1.4 | 0.105 | 1.57 | Adhesive (2a) | 2.5 | 10 | 1.52 |
| Example 10 | Disk-like | Perpendicular | 190 | 1.8 | 0.105 | 1.57 | Adhesive (2a) | 2.5 | 10 | 1.52 |
| Example 11 | Disk-like | Perpendicular | 236 | 2.2 | 0.105 | 1.57 | Adhesive (2a) | 2.5 | 10 | 1.52 |
| Example 12 | Rod-like | Horizontal | 220 | 2.0 | 0.110 | 1.58 | Adhesive (2a) | 2.5 | 10 | 1.52 |
| Example 13 | Disk-like | Perpendicular | 168 | 1.6 | 0.105 | 1.57 | Adhesive (2a) | 11 | 17 | 1.52 |
| Example 14 | Disk-like | Perpendicular | 168 | 1.6 | 0.105 | 1.57 | Adhesive (2a) | 2.5 | 31 | 1.52 |
| Example 15 | Disk-like | Perpendicular | 168 | 1.6 | 0.105 | 1.57 | Adhesive (2a) | 2.5 | 45 | 1.52 |
| Example 16 | Disk-like | Perpendicular | 168 | 1.6 | 0.105 | 1.57 | Adhesive (2a) | 2.5 | 61 | 1.52 |
| Example 17 | Disk-like | Perpendicular | 168 | 1.6 | 0.105 | 1.57 | Adhesive (2a) | 2.5 | 3 | 1.52 |
| Example 18 | Disk-like | Perpendicular | 168 | 1.6 | 0.105 | 1.57 | Adhesive (2a) | 2.5 | 10 | 1.52 |
| Example 19 | Disk-like | Perpendicular | 168 | 1.5 | 0.116 | 1.57 | Adhesive (2a) | 2.5 | 10 | 1.52 |
| Comparative | Disk-like | Perpendicular | 168 | 1.4 | 0.120 | 1.57 | Adhesive (2a) | 2.5 | 10 | 1.52 |
| Example 1 | | | | | | | | | | |
| Comparative | Disk-like | Perpendicular | 168 | 2.6 | 0.065 | 1.57 | Adhesive (2a) | 2.5 | 10 | 1.52 |
| Example 2 | | | | | | | | | | |

TABLE 2

| | Second optically anisotropic layer | | | | | Evaluation of display performance | | | |
|---|---|---|---|---|---|---|---|---|---|
| | | Alignment | Film | Average | | | Tint | | |
| | Type of | state of | thick- | refrac- | Optical film | | azimuthal | In-plane | Air bubbles |
| | liquid | liquid | ness | tive | Re | Front | angle | tint | during |
| | crystal | crystal | (μm) | index | (nm) | tint | dependence | unevenness | bonding |
| Example 1 | Rod-like/rod-like | Twisted/perpendicular | 2.3 | 1.58 | 141 | A | A | A | N |
| Example 2 | Rod-like/rod-like | Twisted/perpendicular | 2.3 | 1.58 | 141 | A | A | B | N |
| Example 3 | Rod-like/rod-like | Twisted/perpendicular | 2.3 | 1.58 | 141 | A | A | A | N |
| Example 4 | Rod-like/rod-like | Twisted/perpendicular | 2.3 | 1.58 | 141 | A | A | B | N |
| Example 5 | Rod-like/rod-like | Twisted/perpendicular | 2.3 | 1.58 | 141 | A | A | A | N |
| Example 6 | Rod-like/rod-like | Twisted/perpendicular | 2.3 | 1.58 | 141 | A | A | A | N |
| Example 7 | Rod-like/rod-like | Twisted/perpendicular | 2.3 | 1.58 | 141 | A | A | A | N |
| Example 8 | Rod-like/rod-like | Twisted/perpendicular | 2.3 | 1.58 | 141 | A | A | B | N |
| Example 9 | Rod-like/rod-like | Twisted/perpendicular | 2.3 | 1.58 | 143 | A | B | B | N |
| Example 10 | Rod-like/rod-like | Twisted/perpendicular | 2.3 | 1.58 | 135 | A | C | A | N |
| Example 11 | Disk-like | Perpendicular | 1.1 | 1.58 | 143 | B | C | A | N |
| Example 12 | Disk-like | Perpendicular | 1.1 | 1.58 | 144 | B | C | A | N |
| Example 13 | Rod-like/rod-like | Twisted/perpendicular | 2.3 | 1.58 | 140 | A | A | B | N |
| Example 14 | Rod-like/rod-like | Twisted/perpendicular | 2.3 | 1.58 | 140 | A | A | B | N |
| Example 15 | Rod-like/rod-like | Twisted/perpendicular | 2.3 | 1.58 | 140 | A | A | C | N |
| Example 16 | Rod-like/rod-like | Twisted/perpendicular | 2.3 | 1.58 | 140 | A | A | C | N |
| Example 17 | Rod-like/rod-like | Twisted/perpendicular | 2.3 | 1.58 | 140 | A | A | A | Y |
| Example 18 | Rod-like/rod-like | Twisted/perpendicular | 2.3 | 1.58 | 141 | A | A | B | N |
| Example 19 | Rod-like/rod-like | Twisted/perpendicular | 2.3 | 1.58 | 141 | A | A | B | N |
| Comparative | Rod-like/rod-like | Twisted/perpendicular | 2.3 | 1.58 | 140 | A | A | D | N |
| Example 1 | | | | | | | | | |
| Comparative | Rod-like/rod-like | Twisted/perpendicular | 2.3 | 1.58 | 140 | A | D | A | N |
| Example 2 | | | | | | | | | |

From the results shown in Tables 1 and 2, it was found that, in the polarizing plate according to the embodiment of the present invention which was applied to a display element to obtain a display device, the in-plane tint unevenness was unlikely to occur and the tint azimuthal angle dependence was suppressed in a case where the display device was viewed in a black display state from an oblique direction.

From the comparison of Examples 1 and 2 and Examples 13 to 17, it was found that, in a case where the thickness unevenness σ of the intimate attachment layer was 35 nm or less, the in-plane tint unevenness was less likely to occur, and in a case where the thickness unevenness σ of the intimate attachment layer was less than 10 nm, the in-plane tint unevenness was less likely to occur. In addition, it was found that, in a case where the thickness unevenness σ of the intimate attachment layer was 5 nm or more, the air bubbles during bonding could be suppressed.

From the comparison of Examples 1 and 2 and Examples 13 to 17, it was found that, in a case where the film thickness of the intimate attachment layer was 10 μm or less, the in-plane tint unevenness could be further suppressed.

From the comparison of Example 2 and Examples 5 to 8, it was found that, in a case where the value (Re/d) obtained by dividing the in-plane retardation Re of the first optically anisotropic layer at a wavelength of 550 nm by the thickness d of the first optically anisotropic layer was 0.110 or less, the in-plane tint unevenness could be further suppressed.

From the comparison of Example 2 and Examples 9 to 12, it was found that, in a case where the in-plane retardation of the first optically anisotropic layer at a wavelength of 550 nm was 150 to 180 nm, the tint azimuthal angle dependence could be further suppressed, and in a case where the in-plane retardation of the first optically anisotropic layer at a wavelength of 550 nm was 160 to 180 nm, the tint azimuthal angle dependence could be further suppressed.

From the comparison of Example 2 and Examples 9 to 12, it was found that, in a case of the polarizing plate of the aspect 1, the tint in a case of being observed from the front direction could be further suppressed.

### Example 20

<Formation of Optically Anisotropic Layer (1p)>

A composition (1p) for forming an optically anisotropic layer, containing a disk-like liquid crystal compound and having the following composition, was applied onto the above-described cellulose acylate film using a Geeser coating machine to form a composition layer. The film on which the composition layer had been formed was heated with hot air at 116° C. for 1 minute, and irradiated with ultraviolet rays having an irradiation amount of 150 mJ/cm² at 78° C. using a 365 nm UV-LED while purging with nitrogen so as to have an atmosphere having an oxygen concentration of 100 ppm by mass or less. Thereafter, the obtained coating film was annealed with hot air at 115° C. for 25 seconds to form an optically anisotropic layer (1p) (corresponding to a negative C-plate).

A film thickness of the formed optically anisotropic layer (1p) was 0.9 μm. An in-plane retardation Re at a wavelength of 550 nm was 0 nm, and a retardation Rth in a thickness direction at a wavelength of 550 nm was 40 nm. It was confirmed that an average tilt angle of a disc plane of the disk-like liquid crystal compound with respect to the film surface was 0°, and the disk-like liquid crystal compound was horizontally aligned with respect to the film surface.

Composition (1p) for forming optically anisotropic layer

| | |
|---|---|
| Disk-like liquid crystal compound 1 shown above | 4 parts by mass |
| Disk-like liquid crystal compound 2 shown above | 1 part by mass |
| Disk-like liquid crystal compound 3 shown below | 95.0 parts by mass |
| Ethylene oxide-modified trimethylolpropane | 20.0 parts by mass |
| triacrylate (V # 360, manufactured by Osaka | |
| Organic Chemical Industry Ltd.) | |
| Polymerization initiator S-1 | 3.0 parts by mass |
| (oxime type) shown above | |
| Fluorine-containing compound B shown above | 0.6 parts by mass |
| Methyl isobutyl ketone | 361 parts by mass |
| Ethyl propionate | 90 parts by mass |
| Methyl ethyl ketone | 24 parts by mass |

Disk-like liquid crystal compound 3

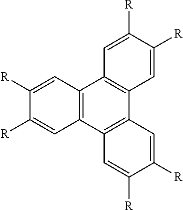

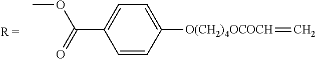

### <Production of Polarizing Plate>

The coating surface (exposed surface) of the optically anisotropic layer (1p) was subjected to a corona discharge treatment. Conditions of the corona discharge treatment were set to an output intensity of 2.5 kW, a line speed of 18 m/min, an electrode length of 1.4 m, and a gap distance of 2 mm. The above-described adhesive (2a) was applied onto the treated surface subjected to the corona treatment such that the film thickness was 1.5 μm. The surface of the elongated linear polarizer produced by the same method as in Example 1, opposite to the polarizer protective film side, and the surface of the above-described optical film (1p) on which the adhesive (2a) was applied were bonded to each other, and the adhesive (2a) was cured by the same method as described above to obtain a laminate of linear polarizer-optically anisotropic layer (1p). The cellulose acylate film of the optically anisotropic layer (1p) was peeled off to expose the surface of the optically anisotropic layer (Ip) in contact with the cellulose acylate film, and the surface was subjected to a corona discharge treatment. Conditions of the corona discharge treatment were set to an output intensity of 2.5 KW, a line speed of 18 m/min, an electrode length of 1.4 m, and a gap distance of 2 mm.

The exposed surface of the optical film (1a-1b-1c) on which the surface of the optically anisotropic layer (1a) in contact with the cellulose acylate film was exposed was subjected to a corona discharge treatment by the same method as in Example 1, and then the adhesive (2a) was applied such that the film thickness was 1.5 μm.

The surface of the produced laminate of linear polarizer-optically anisotropic layer (Ip), subjected to the corona discharge treatment, and the surface of the optical film (1a-1b-1c) on which the adhesive (2a) was applied were bonded to each other, and the adhesive (2a) was cured by the same method as described above to obtain a laminate of linear polarizer-adhesive layer (2a)—optically anisotropic layer (1p)—adhesive layer (2a)—optically anisotropic layer (1a)—adhesive layer (2a)—optically anisotropic layer (1b-1c). Subsequently, the cellulose acylate film on the optically anisotropic layer (1b-1c) side was peeled off to expose the surface of the optically anisotropic layer (1b-1c) in contact with the cellulose acylate film. As a result, a polarizing plate (P22) including the optical film (1p-1a-1b-1c) and the linear polarizer was produced. In the polarizing plate (P22), the polarizer protective film, the polarizer, the optically anisotropic layer (1a), the adhesive layer (2a), the optically anisotropic layer (1b), and the optically anisotropic layer (1c) were laminated in this order, and the polarizing plate (P22) corresponded to the polarizing plate of the aspect 1. An in-plane retardation of the above-described optical film (1p-1a-1b-1c) at a wavelength of 550 nm was within a range of 130 to 150 nm.

In a case where the polarizing plate was evaluated by the same method as in the above-described polarizing plate (P1), it was found that, in the polarizing plate which was applied to a display element to obtain a display device, the in-plane tint unevenness was unlikely to occur and the tint azimuthal angle dependence was suppressed in a case where the display device was viewed in a black display state from an oblique direction. In addition, the thickness unevenness σ of the intimate attachment layer was 35 nm or less.

### Example 21

<Production of Glass with AR Layer>

An inorganic oxide layer (AR layer) was formed on a chemically strengthened glass. Specifically, the AR layer was formed by a sputtering method under any film formation pressure conditions, and a film was formed such that the layer structure was Nb₂O₅/SiO₂/Nb₂O₅/SiO₂ from the glass side and the film thickness of each layer was 15 nm/25 nm/105 nm/85 nm, thereby producing a glass with an AR layer.

The glass with an AR layer was bonded to the surface of the display element on which the polarizing plate (P22) produced in Example 20 was bonded, and the evaluation was performed by the same method as in the above-described polarizing plate (P1). As a result, it was found that, in the polarizing plate which was applied to a display element to obtain a display device, the in-plane tint unevenness was unlikely to occur and the tint azimuthal angle dependence was suppressed in a case where the display device was viewed in a black display state from an oblique direction. In addition, the thickness unevenness σ of the intimate attachment layer was 35 nm or less.

### Example 22

<Formation of Optically Anisotropic Layer (2p)>

The following composition was put into a mixing tank, stirred, and heated at 90° C. for 10 minutes. Thereafter, the obtained composition was filtered through a filter paper having an average hole diameter of 34 μm and a sintered metal filter having an average hole diameter of 10 μm to prepare a dope. The concentration of solid contents of the dope was 23.5% by mass, and the solvent of the dope was methylene chloride/methanol/butanol=81/18/1 (mass ratio).

Cellulose acylate dope

| | |
|---|---|
| Cellulose acylate (acetyl substitution degree: 2.86, viscosity | 100 parts by mass |
| average degree of polymerization: 310) | |
| Sugar ester compound 1 | 6.0 parts by mass |
| Sugar ester compound 2 | 2.0 parts by mass |
| Silica particle dispersion (AEROSIL R972, manufactured by Nippon Aerosil Co., Ltd.) | 0.1 parts by mass |
| Solvent (methylene chloride/methanol/butanol) | |

Sugar ester compound 1 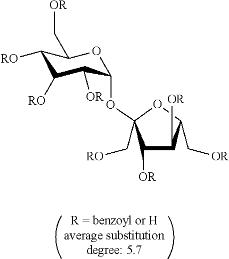
Sugar ester compound 2

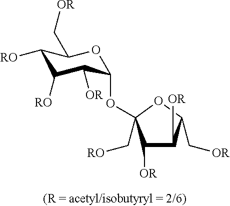

The dope produced above was cast using a drum film forming machine. The dope was cast from a die such that it was in contact with a metal support cooled to 0° C., and then the obtained web (film) was stripped. The drum was made of SUS.

The web (film) obtained by casting was peeled off from the drum, and then dried in a tenter device for 20 minutes at 30° C. to 40° C. during film transport, and the tenter device transported the web by clipping both ends of the web. Subsequently, the web was post-dried by zone heating while being rolled. The obtained web was knurled and then wound up.

In the obtained cellulose acylate film, a film thickness was 40 μm, an in-plane retardation at a wavelength of 550 nm was 1 nm, and a thickness direction retardation at a wavelength of 550 nm was 26 nm. The cellulose acylate film obtained in this way was defined as an optically anisotropic layer (2p).

### <Production of Linearly Polarizing Plate>

As in Example 1, a cellulose triacetate film TJ25 (manufactured by FUJIFILM Corporation; thickness: 25 μm) subjected to an alkali saponification treatment by the same method as in Example 1 was bonded to one surface of the linear polarizer having a thickness of 13 μm by the same method as in Example 1, and the optically anisotropic layer (2p) was bonded to the opposite surface with the above-described PVA adhesive by the same method as in Example 1, thereby producing a linear polarizing plate.

### <Production of Polarizing Plate>

By the same method as in Example 1, the first optically anisotropic layer and the second optically anisotropic layer were produced, and bonded to the optically anisotropic layer (2p) side of the linear polarizing plate to produce a polarizing plate. As a result, a polarizing plate (P22) including the optical film (1a-1b-1c) and the linear polarizer was produced. In the polarizing plate (P22), the polarizer protective film (TJ25), the polarizer, the optically anisotropic layer (2p), the optically anisotropic layer (1a), the adhesive layer (2a), the optically anisotropic layer (1b), and the optically anisotropic layer (1c) were laminated in this order, and the polarizing plate (P22) corresponded to the polarizing plate of the aspect 1.

### Examples 23 and 24

By the same method as in Example 22, the first optically anisotropic layer and the second optically anisotropic layer having optical characteristics shown in Tables 3 and 4 were produced by adjusting the thicknesses of the optically anisotropic layers, and bonded to the optically anisotropic layer (2p) side of the linear polarizing plate to produce a polarizing plate.

TABLE 3

| | First optically anisotropic layer | | | | | | Intimate attachment layer | | | |
|---|---|---|---|---|---|---|---|---|---|---|
| | | Alignment | | Film | | Average | | Film | | Average |
| | Type of | state of | | thick- | | refrac- | Closely | thick- | Thickness | refrac- |
| | liquid | liquid | Re | ness | | tive | attaching | ness | unevenness σ | tive |
| | crystal | crystal | (nm) | (μm) | Re/d | index | agent | (μm) | (nm) | index |
| Example 22 | Disk-like | Perpendicular | 168 | 1.6 | 0.105 | 1.57 | Adhesive (2a) | 2.5 | 5 | 1.52 |
| Example 23 | Disk-like | Perpendicular | 160 | 1.5 | 0.105 | 1.57 | Adhesive (2a) | 2.5 | 5 | 1.52 |
| Example 24 | Disk-like | Perpendicular | 160 | 1.5 | 0.105 | 1.57 | Adhesive (2a) | 2.5 | 5 | 1.52 |

TABLE 4

| | Second optically anisotropic layer | | | | | Evaluation of display performance | | | |
|---|---|---|---|---|---|---|---|---|---|
| | | Alignment | Film | Average | | | Tint | | |
| | Type of | state of | thick- | refrac- | Optical film | | azimuthal | In-plane | Air bubbles |
| | liquid | liquid | ness | tive | Re | Front | angle | tint | during |
| | crystal | crystal | (μm) | index | (nm) | tint | dependence | unevenness | bonding |
| Example 22 | Rod-like/rod-like | Twisted/perpendicular | 2.3 | 1.58 | 141 | A | A | A | N |
| Example 23 | Rod-like/rod-like | Twisted/perpendicular | 2.3 | 1.58 | 143 | A | A | A | N |
| Example 24 | Rod-like/rod-like | Twisted/perpendicular | 2.2 | 1.58 | 144 | A | A | A | N |

In a case where a display element on which the polarizing plates produced in Examples 22 to 24 were bonded was evaluated by the same method as in the above-described polarizing plate (P1), it was found that, in the polarizing plate which was applied to a display element to obtain a display device, the in-plane tint unevenness was unlikely to occur and the tint azimuthal angle dependence was suppressed in a case where the display device was viewed in a black display state from an oblique direction. In particular, in Examples 23 and 24, the tint change in a case of changing the azimuthal angle was small because the reflected tint from the oblique direction was biased toward the bluish direction, and thus a favorable impression was obtained. In addition, the thickness unevenness σ of the intimate attachment layer was 35 nm or less.

### EXPLANATION OF REFERENCES

12A, 12B: first optically anisotropic layer
14A: optically anisotropic layer (A)
16A: optically anisotropic layer (B)
18B: optically anisotropic layer (C)
30A, 30B: polarizer
40A, 40B: intimate attachment layer
100A, 100B: polarizing plate

What is claimed is:

1. A polarizing plate comprising:
a polarizer; and
an optical film,
wherein an in-plane retardation of the optical film at a wavelength of 550 nm is 130 to 150 nm,
the optical film includes a first optically anisotropic layer, an intimate attachment layer, and a second optically anisotropic layer from a polarizer side,
an in-plane retardation of the first optically anisotropic layer at a wavelength of 550 nm is 150 to 240 nm, and
a value obtained by dividing the in-plane retardation of the first optically anisotropic layer at a wavelength of 550 nm by a thickness of the first optically anisotropic layer is 0.07 to 0.116.

2. The polarizing plate according to claim 1,
wherein a thickness unevenness of the intimate attachment layer is 5 to 35 nm.

3. The polarizing plate according to claim 1,
wherein the in-plane retardation of the first optically anisotropic layer at the wavelength of 550 nm is 150 to 180 nm.

4. The polarizing plate according to claim 1,
wherein the first optically anisotropic layer is a layer formed of a composition containing a disk-like liquid crystal compound.

5. The polarizing plate according to claim 1,
wherein a thickness of the intimate attachment layer is 0.5 to 20 μm.

6. The polarizing plate according to claim 1,
wherein the intimate attachment layer is an adhesive layer or a pressure-sensitive adhesive layer.

7. The polarizing plate according to claim 1,
wherein the in-plane retardation of the optical film at the wavelength of 550 nm is 135 to 145 nm.

8. A display device comprising:
a display element; and
the polarizing plate according to claim 1.
